(19) United States
(12) Patent Application Publication
(10) Pub. No.: US 2007/0088997 A1
(43) Pub. Date: Apr. 19, 2007

(54) GENERATION AND SELF-SYNCHRONIZING DETECTION OF SEQUENCES USING ADDRESSABLE MEMORIES

(76) Inventor: Peter Lablans, Morris Township, NJ (US)

Correspondence Address: Glen M. Diehl;DIEHL SERVILLA LLC, Suite 110, 77 Brant Ave., Clark, NJ, 07066, US

(21) Appl. No.: 11/534,837

(22) Filed: Sep. 25, 2006

Related U.S. Application Data
(60) Provisional application No. 60/720,655, filed on Sep. 26, 2005.

(51) Int. Cl. G01R 31/28

(52) U.S. Cl. 714/724

(57) ABSTRACT

Methods and apparatus to implement LFSRs and LFSR based sequence generators, detectors, scramblers and descramblers by addressable memory are disclosed. The methods and apparatus may be processing binary or n-valued symbols, with n>2. Methods to uniquely characterize n-valued Gold sequence are also disclosed. Self-synchronizing methods to detect sequences which can be decomposed into unique words are also disclosed. Methods and apparatus to implement Fibonacci and Galois LFSRs are disclosed.

### CROSS-REFERENCE TO RELATED APPLICATIONS

This application claims the benefit of U.S. Provisional Patent Application Ser. No. 60/720,655, filed Sep. 26, 2005, which is incorporated herein by reference.

### BACKGROUND OF THE INVENTION

The present invention relates to binary and non-binary methods and apparatus for sequence generation, scrambling, and detection such as descrambling and sequence detection. More specifically it relates to methods and apparatus not using LFSRs with a shift register.

LFSR based methods for generating and scrambling binary sequences are widely used in applications such as telecommunications. LFSR based methods can also be used for generating and scrambling non-binary sequences. Sometimes the use of LFSR circuitry is not desirable or possible. Power consumption of high clock rate LFSRs, due to the shift-and-hold aspects of the shift register, is a known concern. In that and other cases equivalent or improved methods and apparatus that provide the same results as LFSRs are required.

### SUMMARY OF THE INVENTION

Before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of the description and should not be regarded as limiting.

It is one aspect of the present invention is to provide addressable memory based methods and apparatus to implement LFSRs.

It is another aspect of the present invention to provide addressable memory based methods and apparatus to detect binary and non-binary pseudo-noise sequences.

It is a further aspect of the present invention to provide addressable memory based methods and apparatus for implementing LFSR based scramblers.

It is another aspect of the present invention to provide addressable memory based methods and apparatus for implementing self synchronizing LFSR based descramblers.

It is a further aspect of the present invention to provide addressable memory based methods and apparatus for detecting binary and non-binary Gold sequences.

It is another aspect of the present invention to provide addressable memory based methods and apparatus for self synchronizing detection of binary and non-binary Gold sequences.

It is a further aspect of the present invention to provide addressable memory based methods and apparatus to implement Galois LFSRs.

### BRIEF DESCRIPTION OF THE DRAWINGS

Various other objects, features and attendant advantages of the present invention will become fully appreciated as the same becomes better understood when considered in conjunction with the accompanying drawings, and wherein:

FIG. 1 is a diagram of an LFSR.

FIG. 2 is another diagram of an LFSR.

FIG. 3 is a diagram of an LFSR based sequence generator.

FIG. 4 is another diagram of an LFSR based sequence generator.

FIG. 5 is a diagram of an LFSR based scrambler.

FIG. 6 is a diagram of another LFSR based scrambler.

FIG. 7 is a diagram of an LFSR based descrambler.

FIG. 8 is a diagram of another LFSR based descrambler.

FIG. 9 is a diagram of an LFSR based sequence generator.

FIG. 10 is another diagram of an LFSR based sequence generator.

FIG. 11 is another diagram of an LFSR based sequence generator.

FIG. 12 is a diagram of an addressable memory based sequence generator.

FIG. 13 is a diagram of an LFSR based sequence generator.

FIG. 14 is a diagram of an addressable memory based sequence generator.

FIG. 15 is another diagram of an addressable memory based sequence generator.

FIG. 16 is another diagram of an addressable memory based sequence generator.

FIG. 17 is a diagram of an LFSR based scrambler.

FIG. 18 is a diagram of an addressable memory based scrambler.

FIG. 19 is a diagram of an LFSR based descrambler.

FIG. 20 is a diagram of an addressable memory based descrambler.

FIG. 21 is a diagram of an LFSR based scrambler.

FIG. 22 is a diagram of an addressable memory based scrambler.

FIG. 23 is a diagram of an addressable memory based scrambler.

FIG. 24 is a diagram of an LFSR based descrambler.

FIG. 25 is a diagram of an LFSR based sequence generator.

FIG. 26 is a diagram of an LFSR based sequence detector.

FIG. 27 is a diagram of an addressable memory based sequence detector.

FIG. 28 is an auto-correlation graph of a Gold sequence.

FIG. 29 is a diagram of an addressable memory based Gold sequence detector.

FIG. 30 is a flow diagram for filling an addressable memory of a Gold sequence detector.

FIG. 31 is a flow diagram for an addressable memory Gold sequence detector.

FIG. 32 is a diagram of an addressable memory based Gold sequence detector.

FIG. 33 is a diagram for initializing a memory from an LFSR.

FIG. 34 is a diagram of an addressable memory based LFSR with an LFSR logic unit.

FIG. 35 is a diagram of an LFSR logic unit.

FIG. 36 is a diagram of a Galois LFSR based sequence generator.

FIG. 37 is a diagram of a Galois LFSR.

FIG. 38 is a diagram of a memory based Galois LFSR.

### DETAILED DESCRIPTION OF THE INVENTION

The inventor has described the rules for creating n-valued LFSR based sequence generators, LFSR based n-valued scramblers and corresponding descramblers in U.S. Non-Provisional patent application Ser. No. 10/935,960, filed on Sep. 8, 2004, entitled TERNARY AND MULTI-VALUE DIGITAL SCRAMBLERS, DESCRAMBLERS AND SEQUENCE GENERATORS, which is incorporated herein by reference in its entirety. LFSR stands for Linear Feedback Shift Register. For the purpose of the present invention a LFSR will be defined. In some cases an LFSR circuit, be it a scrambler or sequence generator will be indicated as an LFSR or an LFSR circuit. In the present invention an LFSR circuit is a circuit (or its corresponding method) having an LFSR. An n-valued LFSR is a shift register of k elements, each element being able to hold an n-valued symbol. Each element has an input and an output. At the occurrence of a clock signal an element of a shift register will assume the value of a symbol provided on its input. The present invention is focused on LFSRs in Fibonacci and Galois configurations. In the Fibonacci configuration the input of the shift register is the input of its first element. An LFSR in the current definition also has feedback taps; the output of the last element of a shift register always has a tap. There is also always one feedback tap on one of the outputs of the other elements of the shift register. Further more an LFSR has at least one and at most (k−1) reversible n-valued logic functions or devices implementing such functions, each function or device having two inputs and one output. One input of a function or a device implementing a function is always connected to an output of an element or to an output of a function. If an LFSR has only one n-valued logic function or device implementing an n-valued logic function, then the output of that function or device is the output of the LFSR. Each input of a function is uniquely connected to an output, no other input of a logic function or device implementing a logic function is connected to that output. It is of course true that an output of an element of a shift register may be connected to an input of a next element and may also be connected to an input of a logic function. However that output is never shared by two or more different inputs of logic functions. When the LFSR has more than one n-valued logic function, then the output of the last n-valued logic function is the output of the LFSR; or in other words the output of the function with one of its inputs connected to the output of an element closest to the input of the shift register is the output of the LFSR.

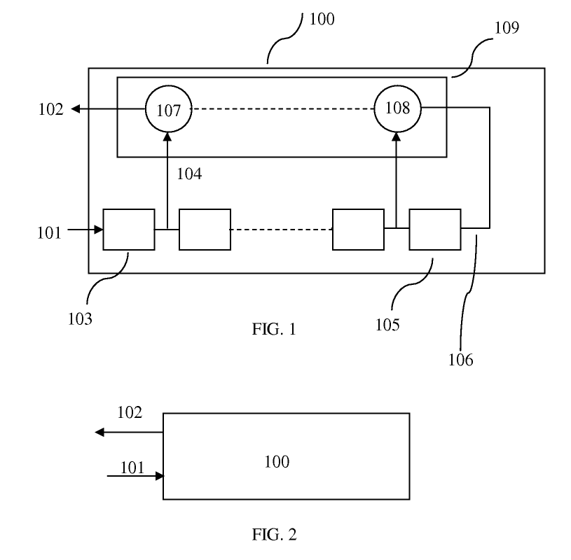

The literature may provide a variety of definitions of an LFSR. For instance an LFSR may be described as what would be called in the present invention a sequence generator. For instance a document published by Texas Instruments in December 1996, number SCTA036A entitled: “What's an LFSR” describes a sequence generator as an LFSR. However for the purpose of describing the present invention, the definition here provided will be used. The definition is illustrated in FIG. 1. The diagram of the LFSR 100 shows an input 101, which is the input to the first storage element 103 of a shift register, also being the input to the shift register and herewith being defined as the input to the LFSR. The storage element 105 is the k^{th} storage element of he shift register. A tap 104 is shown connecting the output of 103 with an input of an n-valued logic function or device 107. The LFSR always has a tap 106 on its last element of the shift register. This tap is always connected to one input of a first device or n-valued logic function 108. N-valued logic function 107 is the last function in the LFSR and its output 102 is the output of the LFSR. It is possible that the LFSR has only one function. However the LFSR always has at least one function or device. In a further definition of an LFSR the logic devices such as 108 and 107 can be considered to be an n-valued “logic unit” of the LFSR, with the taps (such as 104 and 106) as its inputs and 102 (or the output of the LFSR) as its output. The n-valued LFSR logic unit is identified and defined according to 109 in the diagram of FIG. 1. The n-valued LFSR logic unit has at most k inputs when k is the number of shift register elements; it comprises at most d n-valued logic functions or devices that implement such functions, with d≦k−1; and the n-valued LFSR logic unit has an output (102) also being the output of the LFSR.

The LFSR 100 can be illustrated as in the simplified diagram of FIG. 2 just showing the LFSR 100 with input 101 and output 102. As before, the presence of a clock signal is assumed. It should be clear that the LFSR as shown here is merely a building block. To have the LFSR perform a function additional connections have to be provided.

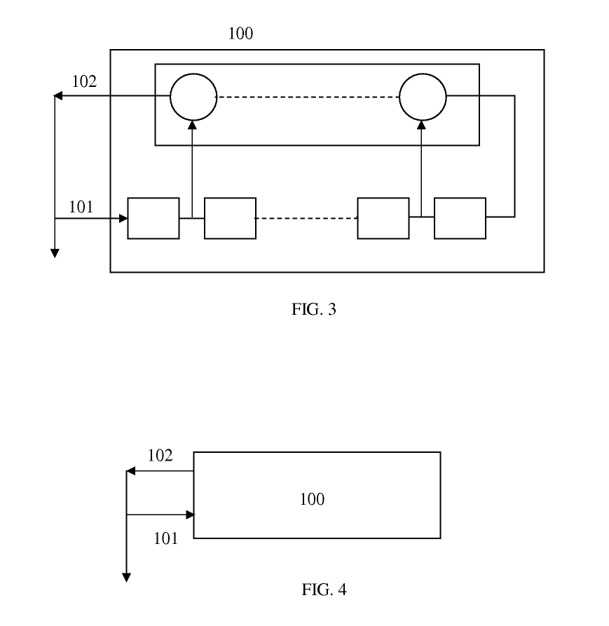

FIG. 3 is a diagram of an LFSR adapted to be an n-valued sequence generator, by connecting the output of the LFSR to the input of the LFSR. A generated sequence will be provided on output 102. A simplified diagram of the LFSR based sequence generator is shown in FIG. 4.

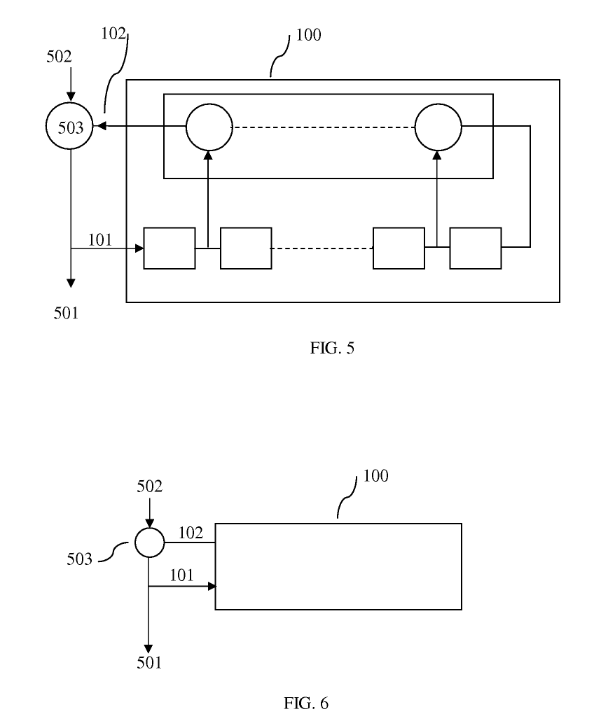

FIG. 5 is a diagram of an LFSR based scrambler. The scrambler is formed by adding a reversible n-valued logic function 503. A first input of the function is connected to the output 102 of the LFSR and the output 501 of the function 503 is connected to the input 101 of the LFSR. A sequence of n-valued symbols can be provided on a second input 502. A scrambled sequence may be provided on 501. The simplified diagram of the scrambler is shown in FIG, 6.

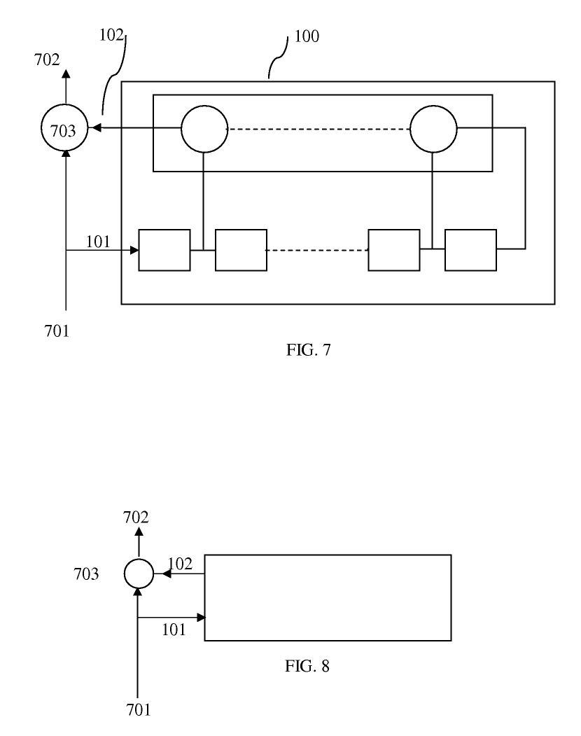

FIG. 7 is a diagram of an LFSR based descrambler corresponding to the scrambler of FIG. 5. The descrambler is created by using the same LFSR 100 with output 102 and input 101. However the n-valued logic function 703 is a reverse of function 503. A first input of 703 is connected with the output 102. A second input of 703 is provided with a sequence of n-valued symbols by an input 701. The same input 701 is also connected to input 101. A (descrambled) sequence is then provided on output 702 of the function 703. A simplified diagram of the descrambler is shown in FIG. 8.

Accordingly is has been shown how three different methods or circuits can be realized by applying the same LFSR as per the definition here applied.

Binary pseudo-noise sequences can be generated by way of LFSR based circuitry or methods. Herein an LFSR generator is under control of a clock signal. In circuits using LFSRs and other circuits shown in figures as an aspect of the present invention a clock signal will not always be drawn or identified. However throughout the description of the present invention the presence or availability of a clock signal is assumed. At the occurrence of the clock signal the content of an element of the shift register is moved to a next element, except the content of the last element, which will be lost.

An LFSR based sequence generator works completely independent of external inputs, after the shift register was initialized as long as a relevant clock signal is available. The only condition is that the initial content of the shift register should not be a forbidden word such as all 0s in a binary case, as under that condition no transition will occur and the signal on the output will remain the same symbol all the time. The process of starting with initial states is called: initiating the LFSR.

State Dependent Generation Method for Binary Sequences

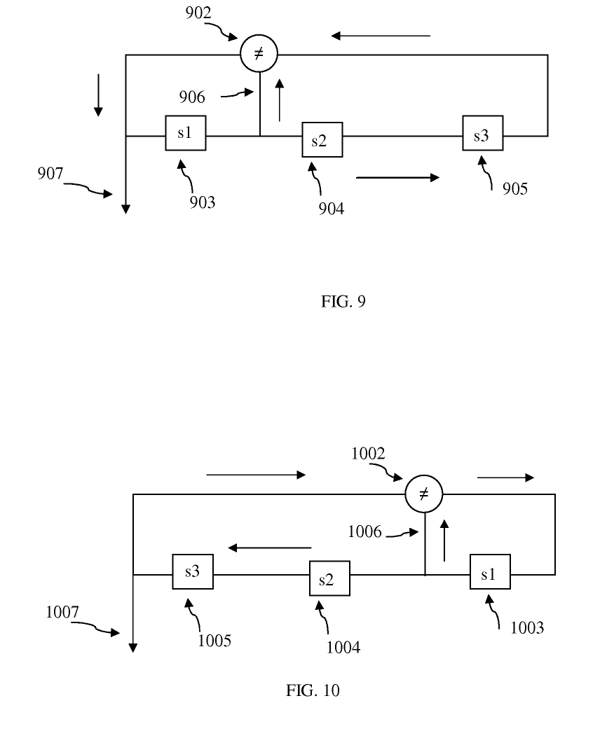

The theoretical basis for designing LFSR based binary sequence generators is known. It applies irreducible polynomials of degree p, wherein p is the number of shift register elements, by selecting the feedback taps corresponding with non-zero coefficients of the terms in the polynomial. It is known that an LFSR based binary sequence generator can create a sequence that is unique in its order of bits and composition of a maximum length of 2^{p}−1. After that number of bits the sequence will start repeating itself. FIG. 9 shows a 3-element LFSR based sequence generator. In the example of FIG. 9 the maximum length of the generated sequence is 2³−1=7.

Another property of the sequence generated by the circuit of FIG. 9 is that each maximum length sequence generated by this circuit depends on the initial content of the shift register. Assuming that initial content [0 0 0] will not occur, under every other initial content of the shift register a maximum length sequence will be generated which all will be cyclical variants of each other. A different way to say this is that all sequences generated by the generator of FIG. 9 depend on the initial content of the shift register and reflect the consecutive contents of the shift register.

For easier analysis it is sometimes more convenient to make the sequence appear to move to the right to the left. This is achieved by the LFSR circuit as shown in FIG. 10. It does not fundamentally change the working of the LFSR, but it changes how the output sequence on 1007 is represented. This is shown in the following table.

| | s3 | s2 | s1 | | | | |
|---|---|---|---|---|---|---|---|
| out1 | 0 | 0 | 1 | 1 | 1 | 0 | 1 |
| out3 | 0 | 1 | 1 | 1 | 0 | 1 | 0 |
| out7 | 1 | 1 | 1 | 0 | 1 | 0 | 0 |
| out6 | 1 | 1 | 0 | 1 | 0 | 0 | 1 |
| out5 | 1 | 0 | 1 | 0 | 0 | 1 | 1 |
| out2 | 0 | 1 | 0 | 0 | 1 | 1 | 1 |
| out4 | 1 | 0 | 0 | 1 | 1 | 1 | 0 |

One may picture that the sequence is already present, but only visible as far as 3 elements are concerned, being the element in the shift register. One can then visualize the generation process as the sequence being pushed through the shift register from right to left. Another way to show the output signals is shown in the following table.

| | s3 | s2 | s1 | | | | | | | | | | |
|---|---|---|---|---|---|---|---|---|---|---|---|---|---|
| out1 | 0 | 0 | 1 | 1 | 1 | 0 | 1 | | | | | | |
| out3 | | 0 | 1 | 1 | 1 | 0 | 1 | 0 | | | | | |
| out7 | | | 1 | 1 | 1 | 0 | 1 | 0 | 0 | | | | |
| out6 | | | | 1 | 1 | 0 | 1 | 0 | 0 | 1 | | | |
| out5 | | | | | 1 | 0 | 1 | 0 | 0 | 1 | 1 | | |
| out2 | | | | | | 0 | 1 | 0 | 0 | 1 | 1 | 1 | |
| out4 | | | | | | | 1 | 0 | 0 | 1 | 1 | 1 | 0 |

Herein the sequence is generated by dropping the first symbol at the beginning and adding a new symbol at the end of the sequence.

This binary example of using a ‘word’ method is provided as an example to show how each state of generating a code (be it binary or non-binary) may be considered to be dependent on its preceding state and the initial state. A coding state is a ‘word’ of symbols. The processes and methods to generate and to detect binary and non-binary sequences is explained in detail in U.S. Provisional Patent Application Ser. No. 60/695,317 filed on Jun. 30, 2005 entitled: The Creation and Detection of Binary and Non-Binary Pseudo-Noise Sequences Not Using LFSR Circuits and in U.S. Non-Provisional patent application Ser. No. 11/427,498 filed on Jun. 29, 2006 entitled The Creation and Detection of Binary and Non-Binary Pseudo-Noise Sequences Not Using LFSR Circuits which are both incorporated herein by reference in their entirety.

The table can be interpreted as follows: the last two elements in the previous state of the shift register are the first two elements of the new state of the shift register. A new method for the generation of pseudo-random sequences and for coding and decoding sequences using a state-machine approach but using memory elements is derived from this observation and is provided as one aspect of the present invention.

The formal method to create pseudo-random binary sequences of length 2^{p}−1 comprises the following steps:
1. assume a word length of p bits;
2. create all possible binary words of p bits;
3. arrange the words in tables such that the first (p−1) bits indicate the row they are in;
3. assume the word with all 0s to be not usable and is a ‘forbidden’ word;
4. start a PN table wherein the first word is comprised of p 1s;
5. complete all PN tables following the path wherein the first (p−1) bits of a word have the last (p−1) bits of the previous word in common
6. each word can only be used once;
7. follow a path such that always the first utmost left, not yet in a path included word in a row is used in a path;
8. a sequence is completed successfully when all allowed words have been used once;
9. a sequence is formed for instance by the first bits of the words, in the order of the achieved path;
10. rearrange all words in a word table in such a way that one word in any row assumes a possible column position it has not previously assumed and start at step 3 again;
11. repeat above steps until all unique word tables have been used;
12. repeat steps 1 to 10 wherein the word with all is is ‘forbidden’ and the all 0 word is the starting word;
   One can of course start the process with any word of length p as long as the ‘forbidden word’ is excluded from the process.

The process as described above allows to create all possible binary PN sequences;

The above method can be used for non-binary sequences of n-valued symbols by substituting the binary elements by n-valued symbols. The steps to be applied are the following:

1. use an n-valued logic with n an integer greater than 2;
2. create all n^{p} digital words of p n-valued elements, with p an integer greater than 1;
3. select one of the words comprised of identical elements as a ‘not-used’ or forbidden word;
4. create a ‘word table’ wherein each row contains the words with identical first (p−1) elements;
5. start a PN table wherein the first word is not the forbidden word;
6. complete the PN tables following the path wherein the first (p−1) bits of a next word have the last (p−1) bits of the previous word in common;
7. each word can only be used once;8. a path is completed when (p−1) different words have been used.
9. a sequence is formed by the first bits of the words, in the order of the achieved path;
   Additional sequences can be created by creating a new ‘word table’ through changing the position of one of the words in a word table.

One can use different ‘forbidden words’. Some of the sequences will end with a word that connects according to the above rules with the first word of the PN table. The sequences thus formed are cyclical and may be formed by LFSR type solutions also. One can of course start the process with any word of length p as long as the ‘forbidden word’ is excluded from the process. The length of a sequence will be (n^{p}−1) digits.

It should be clear that there are many different paths that can be followed in the above method to complete an n-valued sequence. As the word length increases the number of possible paths increases exponentially.

One can also create n-valued sequences of length n^{p} digits by using all p-digit words.

One can build the state machines using addressable memory rather than shift registers to actually generate the sequences. In case of the non-binary sequences, the non-binary sequence elements or digits may be stored in binary form as binary words, of which the bits of the word are used as input signals to a D/A converter, which will generate the non-binary value of the signals.

Memory Based Sequence Generators, Scramblers and Descramblers.

N-valued sequence generators, scramblers and descramblers may be realized by means of computer programs in generic or dedicated processor chips supplied with means to translate generated numerical results into actual n-valued signals and means to receive n-valued signals and transform these into processor usable numerical data.

It is another aspect of the present invention to create configurable binary and non-binary sequence generators and related circuitry by using memory elements with ‘stored’ words, rather than shift registers.

This novel way of realizing LFSR based circuitry applies the fact that each state of the binary or n-valued shift register of p elements is in fact a ‘word’ of length p out of a pre-scribed number of possibilities. For instance in case of an n-valued sequence generator based on an LFSR of p elements it is known that there are n^{p}−1 occurring words and one forbidden word of length p.

The defining characteristic of a shift register of length p is that in each consecutive state of the shift register at least (p−1) elements of a state are identical with (p−1) elements of the preceding and the succeeding state.

The following illustrative examples will be used to demonstrate how memory elements combined with logic functions and address decoders can be used to create binary and n-valued LFSR-based and non-LFSR based sequence generators, scramblers and descramblers.

Memory Based Binary LFSR Based Sequence Generator.

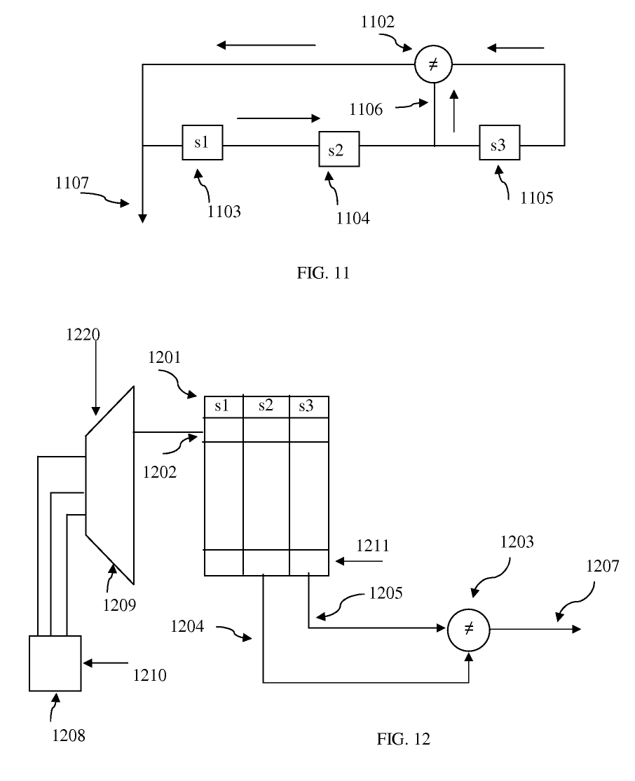

FIG. 11 is a diagram of a 3-element LFSR binary sequence generator that will generate a maximum length sequence of length 7 bits. FIG. 12 shows the diagram of a memory based circuit that can generate the same sequence. It is understood that both circuits need to be controlled by a clock signal to change the state change. In order to keep the drawings simple the clock signal and circuitry are not drawn but should be assumed. The circuit of FIG. 11 has an initial state of elements s1 shown as 1103, s2 shown as 1104 and s3 shown as 1105. On the clock signal the signal which is provided by the output of XOR device 1102 and is provided on 1107 will be moved into 1103. The content of 1103 (s1) will be moved into 1104 (s2). The content of 1104(s2) will be moved into 1105(s3). The original value of 1105 (s3) will be lost. A new signal will be generated on the output of 1102. One may say that the content of the shift register is a new binary word of length 3. The last 2 digits of that word will generate the first digit of the next word on the next clock signal.

The circuit of FIG. 12 includes a memory device 1201, comprising 7 lines of 3 bits words. Each word represents one of 7 possible states of the shift register, organized in this example in the order of occurrence in the LFSR based generator. For instance line 1201 represents the 3 bits word s1, s2, s3 which forms the initial state of the circuit of FIG. 11.

In real life the top line does not need to be the initial state as long as the circuit will start at a line that represents the initial state. However the system needs to start at a certain address. Accordingly a set/reset signal is provided on input 1220. One should configure an address decoder in such a way that when a signal is provided on 1220 the address decoder will jump to an initial address. For practical purposes this address should not represent a forbidden word in sequence generators as this will create a degenerated state of the system. It is also preferable not to use the forbidden word in scramblers, descramblers and detectors that will be described as an aspect of the present invention. In the scrambler/descrambler/detector configuration a forbidden word as the initial address is not catastrophic. However it may make the system more sensitive to certain sequence patterns. In the following realizations of LFSRs and related memory based coders and decoders the set/reset input 1220 may not be specifically identified at every instance. However its presence as well as the circuitry or methods to initiate a starting address is assumed for all of these and is herewith specifically disclosed.

In the system of FIG. 12 when a line in memory 1201 is active its content will be available on as individual outputs representing s2 and s3 on 1204 and 1205 which then will be inputted on XOR device 1203. When the content of the memory 1201 is read in such an order that the read words represent the consecutive states of the LFSR of FIG. 11 then the sequence outputted on 1207 is identical to the sequence on 1107. The addresses are generated by a counter 1208 under control of a clock 1210. The address is provided to an address decoder 1209, which will enable the correct memory line.

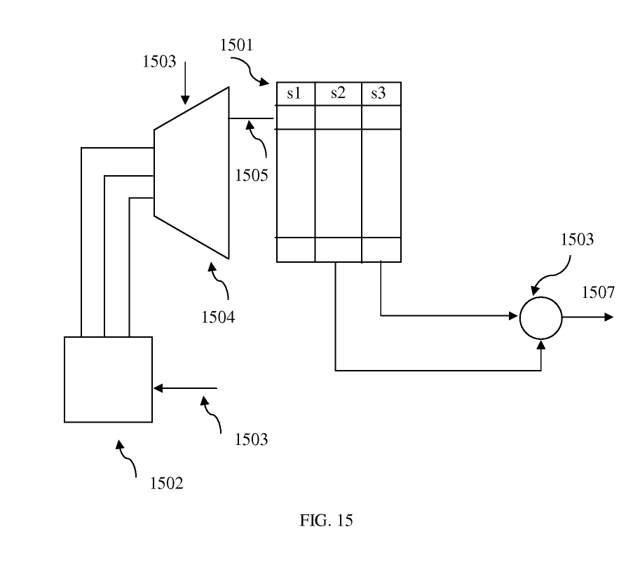

A system has to start from an initial state. In the case of a method or apparatus implemented by an addressable memory, the initial state is a starting address on an address decoder, such as 1504 shown in FIG. 15. It is one aspect of the present invention to start an n-valued LFSR circuit or method implemented by an addressable memory at an address that does not represent a forbidden word if the method implements a sequence generator. A reset facility is contemplated that allows the implementation to be reset to an address that is not representing a forbidden or unwanted state. This initialization facility applies to all illustrative examples provided in the present invention and should be considered a contemplated general facility available to all LFSRs being implemented by addressable memories; even though for simplicity it may not always be identified.

Suppose that the LFSR circuit in FIG. 11 has [1 0 1] as its initial content. The 7 bits generated sequence on 1107 is then [1 1 0 0 1 0 1]. The consecutive states assumed by the shift register are described by the following table:

| s1 | s2 | s3 |
|---|---|---|
| 1 | 0 | 1 |
| 1 | 1 | 0 |
| 1 | 1 | 1 |
| 0 | 1 | 1 |
| 0 | 0 | 1 |
| 1 | 0 | 0 |
| 0 | 1 | 0 |

It should be clear that in the present configuration of FIG. 12 wherein memory elements are read in their physical order only the last two bits of the words are required to generate the sequence as the first bit of each word does not play an active role in determining the output signal. This is of course not the case when the output of the first element is also a feedback tap and contributes to the output signal.

One can change the generated sequence in FIG. 11 on 1107 cyclically by starting with a different initial state. One can change the generated sequence also by changing the XOR function of device 1102 by an EQUAL function. And one can change the sequence by using different taps of the shift register. It should be clear that one can adapt the circuit in FIG. 12 to reflect these changes and generate a sequence on 1207 to be identical to any sequence on 1207.

One can further change the length of the generated sequence of FIG. 11 by increasing the maximum length of the shift register and by increasing the number of taps and consequently of feedback signals. These changes can also be realized in a memory based configuration. The increase of shift register elements will be reflected in the number of bits in a memory word.

Generation of Binary Sequences that Cannot be Realized with LFSR Circuits.

By the nature of binary circuits LFSR they cannot generate (without additional input) generate unique sequences that are longer than 2^{p}−1 bit, when the shift register contains p elements. It was shown that the ‘word’ method can generate additional, different as well as longer sequences. The method using the approach as shown in FIG. 12 can be applied to generate these different sequences. As an example one can for instance insert a ‘forbidden’ word [0 0 0] in the memory. This will increase the length of the sequence with one bit. The following table shows as an illustrative sample a possible new content of the memory of 8 words.

| s1 | s2 | s3 |
|---|---|---|
| 1 | 0 | 1 |
| 0 | 0 | 0 |
| 1 | 1 | 0 |
| 1 | 1 | 1 |
| 0 | 1 | 1 |
| 0 | 0 | 1 |
| 1 | 0 | 0 |
| 0 | 1 | 0 |

With the memory content as shown in the table and with a configuration to use memory words on consecutive memory addresses as shown in FIG. 12 the generated sequence will be: [1 0 1 0 0 1 0 1].

It is possible to switch the order of the words and add previously used words in a different order. For instance one can create as an illustrative example the following table with 11 3-bit words:

| s1 | s2 | s3 |
|---|---|---|
| 1 | 0 | 1 |
| 0 | 0 | 0 |
| 1 | 1 | 0 |
| 1 | 1 | 1 |
| 0 | 1 | 1 |
| 0 | 0 | 1 |
| 1 | 0 | 0 |
| 1 | 0 | 1 |
| 0 | 1 | 0 |
| 1 | 1 | 1 |
| 0 | 1 | 0 |

The above table with the circuits of FIG. 12 will generate: [0 1 0 0 1 0 1 1 0 1].

Three Valued Sequence Generators.

It is another aspect of the present invention to use the ‘word’ method with memory realizations to generate known and novel 3-valued or ternary digital sequences. The inventor has described in U.S. Non-Provisional patent application Ser. No. 11/139,835, filed May 27, 2005, entitled MULTI-VALUED DIGITAL INFORMATION RETAINING ELEMENTS AND MEMORY DEVICES methods and apparatus to create true n-valued latches. One should assume that n-valued memory elements of the present invention are enabled by that invention or are enabled as binary memory storing and addressing words of ‘symbols’. A symbol may be stored as binary elements, or made available as n-valued signals.

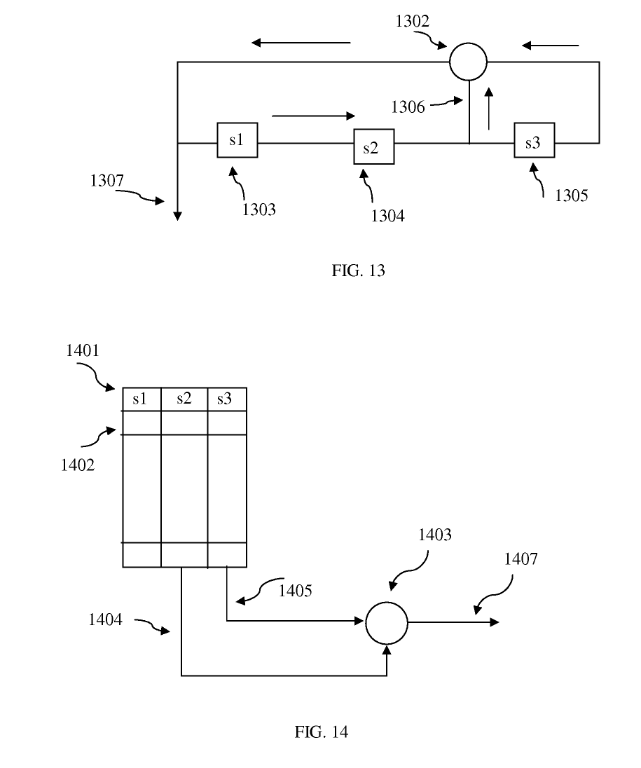

The method will be described by using an illustrative example using the diagrams of FIGS. 13, 14 and 15. FIG. 13 is a diagram of a ternary (or 3-valued) LFSR based sequence generator comprised of a 3-element 3-valued shift register with elements 1303, 1304 and 1305. The outputs of elements 1304 and 1305 are provided as inputs to ternary logic device 1302 which will execute a ternary logic function and provide a ternary signal on output 1307. The circuit according to one aspect of the present invention works under the control of a clock-signal which is not shown but assumed. On a clock signal the content of each element of the shift register is moved one element to the right and the first element will assume the value of the output of the device 1302 before the clock pulse. A new output signal will be generated on 1307.

A maximum length ternary signal generated by the circuit of FIG. 13 will have a length of 3³−1=26 elements. Assume that the device 1302 will execute the following ternary logic truth table.

| fun3 | 0 | 1 | 2 |
|---|---|---|---|
| 0 | 1 | 0 | 2 |
| 1 | 2 | 1 | 0 |
| 2 | 0 | 2 | 1 |

The initial content of the shift register is [1 2 0] and the generated maximum-length ternary sequence of 26 symbols is [0 0 0 1 1 2 1 2 0 2 2 0 1 2 2 2 1 1 0 1 0 2 0 0 2 1].

The shift register with elements 1303, 1304 and 1305 will have the following states as shown in the following table.

| s1 | s2 | s3 |
|---|---|---|
| 1 | 2 | 0 |
| 0 | 1 | 2 |
| 0 | 0 | 1 |
| 0 | 0 | 0 |
| 1 | 0 | 0 |
| 1 | 1 | 0 |
| 2 | 1 | 1 |
| 1 | 2 | 1 |
| 2 | 1 | 2 |
| 0 | 2 | 1 |
| 2 | 0 | 2 |
| 2 | 2 | 0 |
| 0 | 2 | 2 |
| 1 | 0 | 2 |
| 2 | 1 | 0 |
| 2 | 2 | 1 |
| 2 | 2 | 2 |
| 1 | 2 | 2 |
| 1 | 1 | 2 |
| 0 | 1 | 1 |
| 1 | 0 | 1 |
| 0 | 1 | 0 |
| 2 | 0 | 1 |
| 0 | 2 | 0 |
| 2 | 0 | 0 |

The LFSR has the forbidden state [0 0 2]. The memory circuit or method of FIG. 14 is equivalent to the LFSR based circuit of FIG. 13. The memory 1401 comprises the words in the same order as in the table. The device 1403 executes the ternary function with truth table fun3. The control of the circuits can be achieved by using the configuration of FIG. 15 wherein 1502 is a ternary counter, counting from 1 to 26 and inputting the digits in parallel fashion into memory address decoder 1504 which will enable the appropriate memory line 1505. A clock signal is provided on 1503.

One can change the generated sequence in the method of FIG. 15 cyclically by starting the generation process at a place different than the first memory line. One can change the generated sequence by changing the using the same words but changing the internal order of the words. One can change the generated sequence by applying other ternary functions to be implemented by the device 1403/1503. And one can change the generated sequence by changing the place of the taps, the number of taps and functions and of course by changing the number of elements of the ‘word’ (which is equivalent with adding elements to the shift register). The generated sequence on output 1407/1507 can be changed by storing different tables in the memory. As a result of those changes one may in some cases generate ternary sequences that cannot be generated by LFSR based generators.

It should be clear that in the method here provided the width of the memory line is determined by the necessary signals to generate the output signal for the sequence. In the case of the illustrative example two symbols (not 3) are required to generate a symbol for the sequence. If there is a need for more signals, because the equivalent LFSR for instance has a greater number of taps, then the width of memory is greater. In that case it may be more advantageous to just store the symbol to be generated and limit the width of the memory to one symbol.

One can generate sequences that can definitely not be generated by LFSR circuits like in FIG. 13 by adding for instance the forbidden word to the address and content of the memory. For instance one can add the forbidden word so that the method of FIG. 14/15 will generate a unique sequence of 27 symbols.

N-valued Sequence Generators

It should be clear that the methods described for binary and ternary sequences can be applied to generate n-valued sequences using memory ‘word’ methods. It is also possible to form the next address for the memory in different ways. First of all one could include in the content of an address line the address or a pointer to an address that would identify the next address line. Another way is to use the feedback result and the status of the current address. Using again the LFSR based generator of FIG. 13 as an illustrative example one can see that the current status of the shift register is [s1 s2 s3] while the next status will be [b1 s1 s2]. Herein b1 is the result outputted on 1307 generated from [s1 s2 s3]. Accordingly one can make the content of the memory-line [s1 s2 s3], reflecting the content of the next status of the next cycle. In that case one does not need the switching element 1502, but should feed [s1 s2 s3] directly into address decoder 1504.

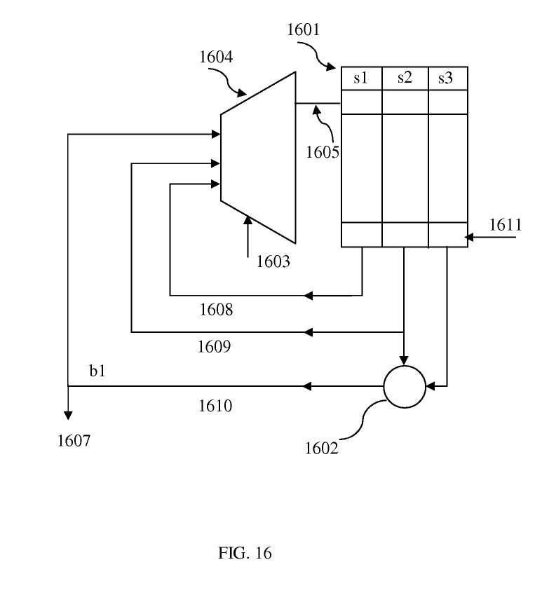

A novel way to implement LFSRs with addressable memory is one aspect of the present invention and is shown in FIG. 16. In the shown case in FIG. 16 one feeds s2 and s3 into the logic device 1602 to create an output signal b1 on 1607. One also feeds [s1 s2] combined with b1 as [b1 s1 s2] as the new address into the address decoder 1604. So each state of the circuit of FIG. 16 determines the next state of the circuit and consequently acts as an LFSR. The circuit is controlled by clock signal 1603.

The circuit of FIG. 16 has signal feedback. One would like to prevent race conditions or instabilities that occur because input signals are changing while still being processed. When one implements the steps of the present invention in a processor, the step between instructions will generally assure that race conditions will not occur. In physical circuitry it may be necessary to prevent unstable conditions. Accordingly, where required one should make the content of a memory line such as shown in FIG. 16 available on a clock controlled temporary storage or buffer such as line 1611, which will indicate the buffer with outputs as well as a controlling clock signal. This should be structured in such a way that the buffer 1611 will maintain the content of an enabled memory line for a certain period and will only assume the content of the newly enabled memory line after a certain delay. This is one possible way to assure that the input on the address decoder does not change because the output of the memory is changing faster than the address coder can process.

This coordination between output of the memory and input to the address decoder may be controlled with clock signals. Accordingly one may also prevent unwanted changes in the output of the enabled memory line by appropriate use of a clock signal 1603. For instance after the occurrence of a clock signal 1603 a memory line is enabled. A change to another enabled memory line will only happen after clock signal 1603 occurs again. If desired one can use both or either a buffer 1611 and a clock signal 1603 to prevent race conditions. While this aspect may not be shown in all individual examples of LFSR realizations by memory it should be assumed to be present and is herewith disclosed as such.

Memory Based LFSR Scrambler Equivalents

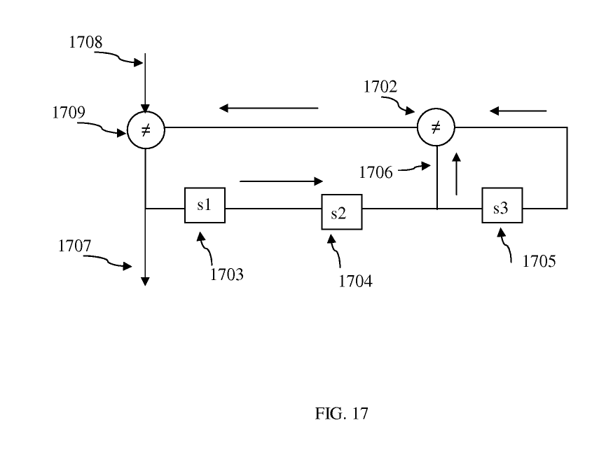

Avoiding the use of shift registers in LFSR based scramblers may sometimes be desirable, for instance for reasons of power dissipation at certain clock speeds. It is possible to avoid shift registers in LFSR scramblers by using addressable memory. A diagram of an LFSR based binary scrambler is shown in FIG. 17. It looks similar to a sequence generator, with the difference that a binary XOR device 1709 is inserted which has as its inputs the output of XOR device 1702 and a signal to be scrambled provided by input 1708. An LFSR scrambler in memory configuration should have all possible binary words of in this case 3 symbols, as all words may occur as the LFSR state. The output 1707 provides the scrambled signal. For illustrative reasons only this configuration has been kept simple with a 3-elements shift register and just one feedback function. It should be clear that more complex configurations are possible.

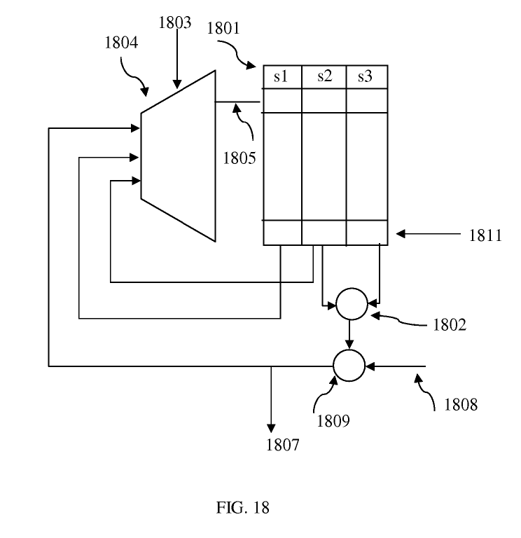

Based on other aspects of the present invention it should be clear that the state of the LFSR can at any time be one of 8 states, as opposed to 7 states in a sequence generator where one excludes the forbidden state. For practical reasons one should prevent input signals of long series 0s occurring when the state of the shift register is [0 0 0]. However that is a practical reason for avoiding long series of 0s, not an operational limitation of the scrambler. The last 2 bits of the new state of the shift register will be the first 2 bits of the previous state of the shift register and the first bit of the new state of the shift register will be the bit generated by combining the last two bits of the shift register of the previous state by a XOR function and combining that result by a XOR function with the binary value of the incoming (and to be scrambled) signal. One may consider the new state thus generated by the old state a memory address to a memory with the content equivalent to the memory address. The content of the memory address represents the correct state of a binary LFSR based scrambler. It should be clear that the method explained in the illustrative example works for all binary LFSR based scramblers. The realization of the scrambler of FIG. 17 by way of a memory method is shown in FIG. 18. All possible states of the shift register of the LFSR of FIG. 17 are stored in the 8 lines, 3 elements addressable memory 1801. Assume the line 1805 is enabled, representing the state of the shift register while a new symbol is incoming. The elements of s2 and s3 in 1801 of the enabled line are inputted to device 1802, which is equivalent with 1702 of the scrambler which is a XOR device. The output of device 1802 is provided to an input of 1809 which is a XOR device equivalent with 1709 in FIG. 17. Also the symbol to be scrambled is provided on input 1808 of 1809. The result, the scrambled signal, is provided on output 1807 and is provided to address decoder 1804 as the first symbol of the next memory address, representing the new LFSR state. Also the content of s1 and s2 of the enabled memory line are provided to address decoder 1804 as second and third symbol of the new memory address. On a clock pulse on 1803 the new address will be decoded and a new memory line will be activated. Consequently according to one aspect of the present invention the scrambler of FIG. 17 has been realized by a memory method illustrated in FIG. 18. A clock controlled buffer 1811 may additionally be used to temporarily store the output of the enabled memory line and make the symbols available to the relevant inputs, ensuring that no race conditions will occur.

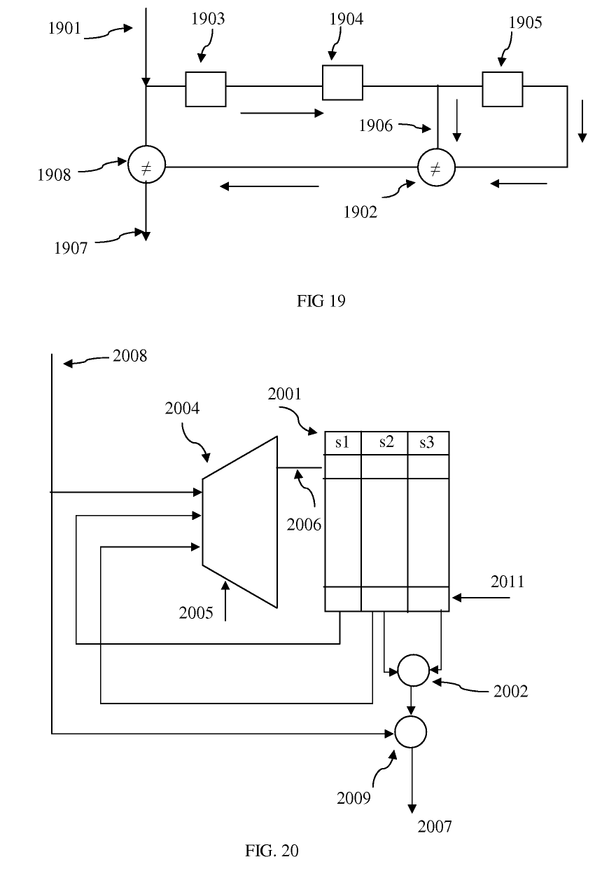

It is another aspect of the present invention to use memory based methods to descramble the signal created by an LFSR equivalent scrambler method. The known configuration of a binary LFSR based descrambler is shown in FIG. 19. A to be descrambled digital signal is provided on 1901. On each clock signal a bit of the incoming signal is inputted into the shift register. The content of shift register elements 1904 and 1905 are inputted into XOR device 1902. The signal generated by 1902 and the signal on 1901 are inputted into XOR device 1908. This device generates a signal on 1907. When the initial state of the LFSR is identical to the initial state of the scrambler then the output on 1907 is identical to the original sequence that was scrambled by the corresponding scrambler. In case the initial states of scrambler and descrambler are different the signal on 1907 can only differ in the first 3 bits from the original to be scrambled sequence in this configuration. This is known as the ‘flushing effect’.

The ‘memory’ method of the LFSR based descrambler is shown in FIG. 20. Assume for illustrative purposes that initially memory line 2006 is enabled and the 3-bits word on that address is made available. To prevent race conditions, as explained earlier, the symbols outputted by the memory line may be temporarily stored in a clock controlled buffer 2011 and outputted from there to the circuits and address decoder. The first two bits will act as the last two bits of a new address. The last two bits will be inputted into XOR device 2002. Its result will be inputted into XOR device 2009. The incoming scrambled signal is provided on 2008 and inputted into XOR device 2009. The output 2007 of 2009 will provide the descrambled signal when corresponding states of scrambler and descrambler were identical. The scrambled signal and the first two bits of the enabled memory line form the address for the next memory line, which will have its memory address as its content. The address information is provided to address decoder 2004. The address decoder 2004 is enabled by a clock signal 2005. The state of the descrambler will conform with the corresponding scrambler in this illustrative example at a maximum after 3 cycles, after which the descrambler has been ‘flushed’ and the descrambler of FIG. 20 will generate the correct descrambled signal. It should be clear that the descrambling method using addressable memory devices also applies to descramblers for scramblers with shift register length different than 3 and taps different or in addition to the tap on the next to last register element.

The 3-valued Memory Based Equivalent of LFSR Scramblers and Descramblers

The ‘addressable memory’ method can also be applied to 3-valued and n-valued scramblers and descramblers with n greater than 3, which is another aspect of the present invention. As an illustrative example both a 3-valued LFSR based scrambler and descrambler will be described. A difference with the binary case is that the applied n-valued logic devices in the scrambler and descrambler solutions are of course non-binary. Also the addressable memory and the address coder operate on n-valued symbols. It is of course possible to have n-valued symbols represented as binary words and adapt all circuitry and methods accordingly. This method of n-valued symbol representation is fully contemplated, and in fact provides including the usage of A/D and D/A converters a complete enablement of n-valued methods in binary technology.

The rules for corresponding LFSR based n-valued scramblers and descramblers was explained by the inventor in U.S. Non-Provisional patent application Ser. No. 10/935,960, filed on Sep. 8, 2004, entitled TERNARY AND MULTI-VALUE DIGITAL SCRAMBLERS, DESCRAMBLERS AND SEQUENCE GENERATORS, which is incorporated herein in its entirety by reference.

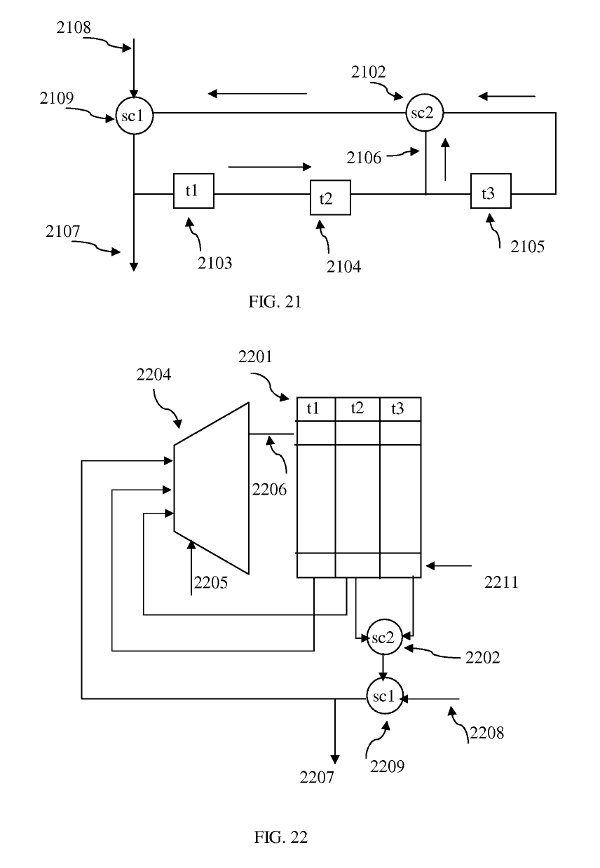

FIG. 21 shows a 3-element ternary or 3-valued LFSR based scrambler. A ternary signal is provided by input 2108 to a ternary logic device 2109 with a ternary reversible logic function sc1. A second input to device 2109 provides the signal on the output of ternary logic device 2102. The device 2102 also executes a reversible ternary logic function. The devices 2102 and 2109 may execute the same function, but don't have to.

FIG. 22 shows as an illustrative example a realization of the LFSR ternary scrambler of FIG. 21 applying a 3-valued addressable memory 2201, which is another aspect of the present invention. The ternary memory has to comprise all possible states of the LFSR, so it has in this case 27 different 3-ternary element words. Assume the memory line 2206 is enabled making available a 3-element ternary word. To prevent race conditions, as explained earlier, the symbols outputted by the memory line may be temporarily stored in a clock controlled buffer 2211 and outputted there to the circuits and address decoder. The last two symbols of the memory output are inputted to a device 2202 implementing a reversible ternary logic function sc2. The signal generated by device 2202 is inputted to ternary device 2209 implementing ternary logic function sc1. The ternary signal to be scrambled is also inputted to device 2209. The signal generated by 2209 is the scrambled signal and is provided on output 2207. This scrambled signal will also serve as the first digit of the new address provided to address decoder 2204. The second and third address digits to 2204 are formed by the first and second digit of the output of the active memory. The address decoder 2204 is enabled by a clock signal on 2205.

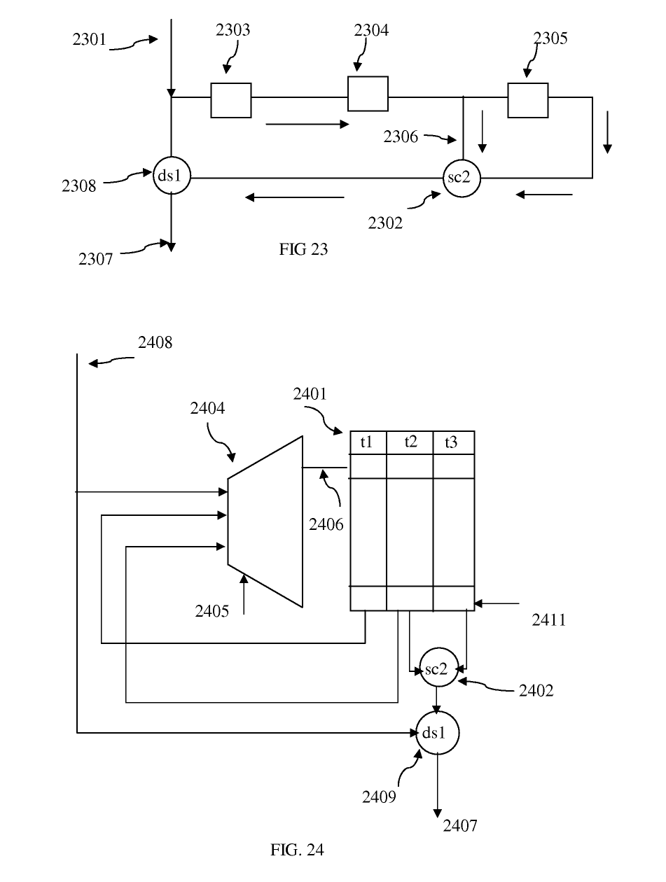

FIG. 23 shows the diagram of the ternary LFSR based descrambler corresponding to the scrambler of FIG. 21. As shown in the earlier cited patent application its ternary device 2302 should execute the ternary logic function sc2 which identical to the function executed by 2102 in the diagram of FIG. 21. However the device 2308 in FIG. 23 should execute the ternary function ds1, wherein ds1 is a reversible ternary logic function that reverses the function sc1 which is executed by 2109 in FIG. 21.

As an illustrative example assume that the ternary logic function sc1 has the following truth table.

| sc1 | 0 | 1 | 2 |
|---|---|---|---|
| 0 | 2 | 0 | 1 |
| 1 | 0 | 1 | 2 |
| 2 | 1 | 2 | 0 |

While the scrambling function is commutative it may be of influence how the device 2308 in FIG. 23 is connected to the inputs. Assume that depending on the state of the signal coming from device 2302 the input provided on 2308 ‘sees’ a column in ds1. That means for the descrambling function ds1′ that the truth table should have ‘reversing’ columns related to sc1, which is shown in the following truth table.

| ds1′ | 0 | 1 | 2 |
|---|---|---|---|
| 0 | 1 | 0 | 2 |
| 1 | 2 | 1 | 0 |
| 2 | 0 | 2 | 1 |

When the device is connected in such a way that the signal provided by 2301 on 2308 ‘sees’ the rows of ds1″ then ds1″ should have reversing columns related to sc1 as is shown in the following truth table.

| ds1″ | 0 | 1 | 2 |
|---|---|---|---|
| 0 | 1 | 2 | 0 |
| 1 | 0 | 1 | 2 |
| 2 | 2 | 0 | 1 |

The diagram of FIG. 24 shows how an addressable ternary 3-symbol word memory with 27 lines can be used as an equivalent of an LFSR based descrambler. The reasoning applied to ternary logic functions sc1, sc2 and d1 also applies to these functions as applied in devices 2402 and 2409. Input 2408 provides the signal to be descrambled and is provided to device 2409. The signal is also provided as the first symbol in the address of the next ternary memory word. The second and third inputs to the address decoder 2404 are provided by the first and second symbol in the memory word 2406 that is currently enabled. To prevent race conditions, as explained earlier, the symbols outputted by the memory line may be temporarily stored in a clock controlled buffer 2411 and outputted there to the circuits and address decoder. A clock signal provided by 2405 will enable address decoder 2404. The active memory enabled by memory line 2406 at this address will have a 3 symbol word reflecting the 3 symbols of its address. It should be clear that this method according to one aspect of the present invention can also be applied to n-valued descrambler with n greater than 3.

Detecting Known Binary and N-valued Sequences

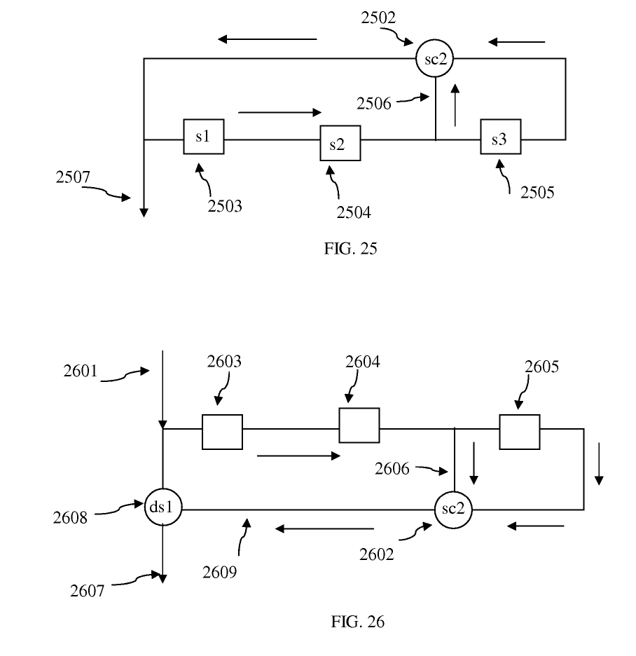

The previous section has shown how to descramble an unknown scrambled sequence of which the method of scrambling was known, by using addressable memory based methods. It is another aspect of the present invention to provide methods to detect known sequences by applying addressable based methods. One aspect of the present invention is to detect maximum-length binary and non-binary Pseudo-Noise or maximum-length sequences, which can be generated by LFSR based methods. FIG. 25 shows a diagram of a 3-element LFSR based sequence generator. For illustrative purposes it is assumed that the circuit will generate a binary m-sequence. In that case the device 2502 may be a binary XOR function and the elements 2503, 2504 and 2505 are binary shift register elements. The binary sequence generated on 2507 has a length of 7 bits. The sequence is cyclically depending on the initial state of the LFSR. The inventor has shown first in U.S. Non-Provisional patent application Ser. No. 11/042,645, filed Jan. 25, 2005, entitled MULTI-VALUED SCRAMBLING AND DESCRAMBLING OF DIGITAL DATA ON OPTICAL DISKS AND OTHER STORAGE MEDIA, which is hereby incorporated by reference in its entirety, that LFSR descrambler type methods or circuits can be used to detect an LFSR generated sequence. This means that in order to detect the sequence as generated by the circuit of FIG. 25 one can use a circuit as shown in FIG. 26. FIG. 26 looks like a descrambler corresponding to the circuit of FIG. 23. It has a similar structure in shift register and the same device executing function for 2602 as its corresponding device 2502 in FIG. 25. However the circuit of FIG. 25 has no corresponding device to device 2608. It can be shown that when the sequence provided to 2601 is generated by the circuit of FIG. 25 then, when the shift registers of generator and detector have identical initial states, the signal at 2601 is identical to the signal at 2609. One way of detecting the presence of a sequence is to generate a sequence of identical symbols on output 2607 for the duration of the detected sequence. Because under the detecting conditions the signals at 2601 and 2609 are identical a sequence of identical symbols in the binary case can be generated by making device 2608 either execute a XOR function, in which case a series of 0s will be generated, or an EQUAL function, in which case a series of 1s will be generated. Detecting may then be achieved by counting the number of consecutive 0s or 1s and assuming that a sequence was detected when a certain number of identical symbols was counted. The counter should be reset at 0 when detection is achieved or if a non-detecting symbol occurs.

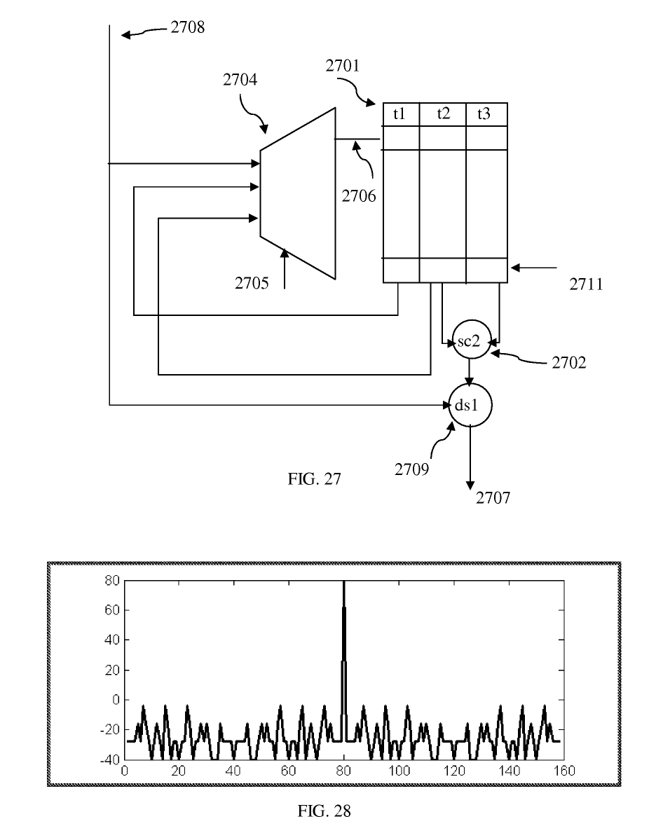

FIG. 27 shows an addressable memory solution for a sequence detector. The memory 2701 in the binary case for a sequence generated by the generator of FIG. 25 must contain 8 3-bit memory lines. While [0 0 0] may be the forbidden word in one configuration it should occur in the detector in case a sequence has this pattern. The method applies a memory address coder 2704, wherein an address is formed by the incoming bit of the sequence and the first two bits of the currently active memory line. It will enable a new memory line when address decoder 2704 is enabled by a clock signal on 2705. The function sc2 executed by 2702 is identical to 2502 of FIG. 25. The function implemented by 2709 may be a XOR function, in which case a detected sequence will generate all 0s on 2707 or an EQUAL function, in which case an all 1 sequence will occur on 2707. The advantage of this detector is that no synchronization is required. The addressable memory solution for this configuration, like the LFSR based descrambler, will be flushed after 3 symbols. One should take account of the flushing effect in the detection level. So it may statistically be more advantageous to use longer sequences to offset the need for ‘flushing’ effects. However when one is fairly confident about the quality (or bit-error-ratio) of the incoming sequence the here described addressable memory method is easy to achieve with no separate needs for synchronization.

The addressable memory detection method can also be applied to ternary and other n-valued maximum length LFSR generated sequences. As an illustrative example a ternary 26 symbols m-sequence detector will be described. Assume that the ternary sequence is generated by a ternary sequence generator described by the diagram of FIG. 25, wherein all devices and memory element are ternary. The sequence can be detected by a method or circuit as shown in FIG. 26 wherein the device 2608 implements a ternary logic function ds1. The function ds1 has to generate identical symbols (all 0s, all 1s or all 2s) when the signals provided by 2601 and 2609 are identical. Further more when these signals are not identical, different symbols have to be generated. The following 3 ternary truth tables are illustrative examples of functions that comply with that requirement.

| ds10 | 0 | 1 | 2 | ds11 | 0 | 1 | 2 | ds12 | 0 | 1 | 2 |
|---|---|---|---|---|---|---|---|---|---|---|---|
| 0 | 0 | 1 | 2 | 0 | 1 | 2 | 0 | 0 | 2 | 0 | 0 |
| 1 | 1 | 0 | 2 | 1 | 2 | 1 | 0 | 1 | 0 | 2 | 0 |
| 2 | 2 | 2 | 0 | 2 | 0 | 0 | 1 | 2 | 0 | 0 | 2 |

The function ds10 will generate all 0s when the signals on 2601 and 2609 are identical and a 1 or a 2 when they are not. Function ds11 will generate all 1s when the signals on 2601 and 2609 are identical and 2s and 0s when they are not. Function ds12 will generate all 2s when 2601 and 2609 are identical and 0s when they are not.

The circuit of FIG. 27 with 2701 an addressable memory of 27 3 symbol lines, 2704 a ternary address decoder and 2702 and 2709 devices that execute the appropriate ternary logic functions will then be an addressable memory based ternary m-sequence detector. One may want to use a clock controlled buffer 2711 to prevent race conditions. Again the flushing effect may be beneficial and allows for detection with no need for synchronization.

It should be clear that this method can also be applied to other n-valued sequences which can be generated by single LFSR circuits.

Detection of Other Known N-valued Sequences

It was shown that the ‘p symbol word’ method can generate n-valued sequences of a maximum length of n^{p} wherein each word will only be used once. This offers the opportunity by detecting a sequence by analyzing the sequence as a series of overlapping and unique words. By determining the order of words one can then detect the appropriate sequence. This was described in U.S. Provisional patent application No. 60/695,317 filed on Jun. 30, 2005 entitled CREATION AND DETECTION OF BINARY AND NON_BINARY PSEUDO-NOISE SEQUENCES NOT USING LFSR CIRCUITS which is hereby incorporated by reference herein in its entirety. A special class of attractive binary and n-valued sequences is formed by Gold-sequences. In a set of Gold-sequences each sequence has an attractive and highly peaked auto-correlation graph and a cross-correlation with other sequences in the set that has no peak and has a very limited value range. Gold sequences are formed by combining two different m-sequences, sequences, usually from different LFSR configurations of identical length of say p elements. While each individual m-sequence can be analyzed in unique words of p symbols, the same is not true of the Gold sequences.

As an illustrative example of the method of detecting known sequences (including Gold sequences) which is another aspect of the present invention, a set of ternary Gold sequences will be used. The following ternary m-sequence of length 80 can be generated by a ternary 4-element LFSR generator: [0 0 2 0 2 0 1 0 1 1 0 1 2 0 1 1 1 2 2 2 1 2 2 0 1 2 1 1 1 0 2 2 0 0 2 1 2 0 0 1 1 2 1 2 1 0 1 0 0 1 0 2 1 0 0 0 0 2 2 2 0 2 2 1 0 2 0 0 0 1 2 2 1 1 2 0 2 1 1]. A set of Gold sequences is formed by cyclically shifting and combining with the following 80 symbol ternary m-sequence: [1 2 1 0 1 1 0 0 1 0 0 0 1 2 1 2 2 0 1 1 1 2 2 2 2 0 2 0 2 1 1 2 0 1 0 2 1 0 0 2 2 1 2 0 2 2 0 0 2 0 0 0 2 1 2 1 1 0 2 2 2 1 1 1 1 0 1 0 1 2 2 1 0 2 0 1 2 0 0 1]. One off the 80 generated ternary Gold sequences is: Gold1=[1 2 2 0 2 1 2 0 0 2 0 2 2 2 0 1 1 2 2 2 2 1 0 0 2 2 0 2 1 0 1 0 1 1 0 0 0 1 0 2 1 0 0 2 0 1 0 2 2 0 2 0 0 0 2 1 1 0 0 0 0 1 2 2 0 0 2 0 1 2 1 2 1 1 2 2 2 1 2 0]. The auto-correlation graph of this sequence is shown in FIG. 21. One can use a computer program to take the first 4 digits of the sequence, determine the decimal value plus 1 of this ternary word, move one digit to the right, determine the next 4 digit word's decimal value plus 1, until one reaches the end of the sequence. This can be done 77 times and can be translated into the following decimal sequence: [52 75 62 24 70 46 57 7 21 63 27 79 74 59 15 45 54 81 80 76 64 30 9 25 75 62 22 65 31 11 32 13 37 28 2 4 12 35 22 64 30 7 20 58 12 36 25 75 61 19 55 3 8 23 67 37 28 1 2 6 18 52 73 57 7 20 60 17 51 71 50 69 45 54 80 78 70]. One can see that some words (for instance 2, 7 and 75) are used more than once. This means one can use a memory based detection method, however some form of synchronization will then be required. When a word is used only once it is possible to start detection without synchronization.

Synchronization in the context of the present invention means “knowing” which word one is dealing with. For instance the word that represents 75 may be the word preceded by 25 and succeeded by 62, or it may be the word representing 75 preceded by 25 and succeeded by 61. So it is possible to distinguish between the two occurrences. However it will require an effort to distinguish between the two situations. It should be clear that in case of a unique word, the address will point immediately to the correct location in the memory, because there is no choice. In such a case no synchronization is required.

One way to achieve a series of unique words in the Gold sequence is by creating words of more than 4 symbols. It can be seen that re-occurring patterns have a maximum length of 7 symbols so that words of length 8 should be unique and enables the creation of a set of Gold sequences of which each can be detected by using an addressable memory method. The above decimal sequence can be expressed in a decimal sequence of 73 numbers formed by 8 symbol words: Gold1_{—}=8=[4201 6040 4998 1870 5610 3708 4563 565 1694 5081 2121 6363 5967 4779 1214 3640 4357 6510 6408 6100 5178 2411 670 2009 6025 4952 1733 5197 2467 838 2513 976 2928 2222 103 307 921 2761 1721 5161 2361 522 1564 4692 952 2854 1999 5997 4868 1481 4441 199 595 1783 5348 2922 2205 52 154 462 1384 4151 5892 4553 537 1610 4829 1365 4095 5724 4049 5586 3634]. This sequence consists of 73 unique 8 symbol ternary words.

One can take another sequence from this set of ternary Gold sequences Gold2=[0 1 1 0 1 1 1 1 1 1 0 0 2 1 1 1 1 1 1 0 1 1 2 2 2 2 2 2 1 0 0 1 0 2 1 0 2 0 2 0 2 1 1 2 1 1 1 1 1 1 2 2 0 1 1 1 1 1 1 2 1 1 0 0 0 0 0 0 1 2 2 1 2 0 1 2 0 2 0 2]. The translation of this sequence into 8 symbol decimal words provides: Gold2_{—}8=[1013 3038 2552 1093 3277 3270 3248 3182 2984 2390 608 1823 5467 3278 3272 3255 3204 3051 2592 1215 3645 4373 6556 6544 6509 6403 6087 5138 2290 309 925 2775 1762 5286 2735 1643 4929 1664 4991 1850 5549 3524 4010 5469 3285 3292 3314 3380 3578 4172 5954 4739 1095 3284 3290 3307 3358 3511 3970 5347 2917 2189 6 18 53 159 475 1424 4272 6253 5637 3787 4800]. The sequence Gold1_8 is significantly different from Gold2_8. All Gold sequences of the set will generate significantly different 8 symbol word sequences.

All Gold sequences of the set generated by two different 4-element ternary LFSRs will generate different 8 symbol word sequences. Not only do words not repeat within a sequence, they will also not repeat within the set of sequences. Consequently decimal numbers based on these words are unique to a sequence of a set. This rule has also been tested on for instance binary Gold sequences, wherein a set of binary Gold-sequences was generated by two 6-elements LFSRs. One can then describe each sequence of that set by 12 bits overlapping words. Each word (and its decimal equivalent) is unique to a sequence and will only appear once in a set of sequences.

Because a multi-symbol word of a certain length is unique to a sequence, this method of analysis provides a basis for detection of individual Gold sequences, which is another aspect of the present invention.

The method of describing Gold sequences generated by combining two sequences generated by two different n-valued sequence generators applying k n-valued symbol words, either in LFSR or the earlier described “word” configuration, as a sequence of unique 2k n-valued symbol words in a set of Gold or Gold-like sequences is one aspect of the present invention. The here provided ternary Gold sequences is an illustrative example, which can be expanded to other n-valued sets of Gold sequences with n≧2. Another aspect of the present invention is the detection of n-valued sequences by way of memory based methods. It is fully contemplated to also generate Gold sequences by way of the here disclosed memory based methods.

One application of n-valued Gold sequences is in pulse position modulation, wherein a train of pulses represents a symbol. A train of pulses may represent a time division channel. So a combined train of pulses may represent different channels. The challenge is that no individual train, under condition of synchronization, should interfere with another train, or are orthogonal. Further more there should be a unique possibility to identify a train of pulses. Pulse trains, transposed according to the decimal number method of Gold sequences as described above will have those properties.

Different variations of the memory based word detection method for binary and n-valued Gold sequences can be developed. Different variations will be described for illustrative purposes, using the previously described set of ternary Gold sequences and 8 symbol ternary words for detection.

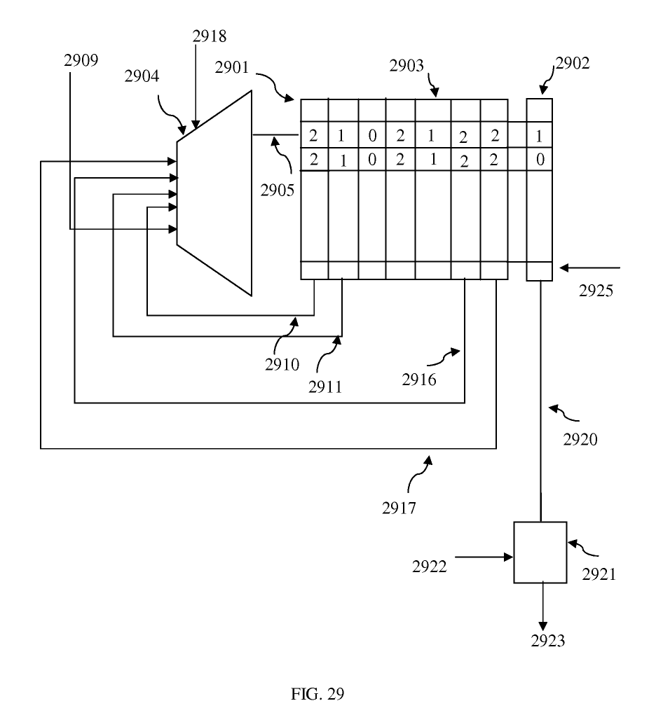

A first illustrative example uses the circuit as shown in FIG. 29. The circuit comprises several components and sub-systems. It applies an addressable memory 2901. There are in total 6561 different ternary words of 8 symbols. The memory 2901 is enabled by an address decoder 2904, having an ability to enable one of 6561 memory lines, depending on the address input. In FIG. 29 line 2905 is assumed to be enabled in this example. One can distinguish two parts in this memory line: section 2903, which includes the first 7 digits or symbols of the currently enabled memory line. The 8^{th} digit of a Gold word is not saved in this example. Assume that the current address is [2 1 0 2 1 2 2 1], which is a valid word in sequence Gold2. The second part of the memory line in a single digit 2902 which will indicate if this memory line represents a word that occurs in the specific Gold sequence that should be detected. In this example that digit is 1, because the memory address represents a valid word.

It should be clear that the method can be used to detect any of the set of Gold sequences, though for the illustrative example only one Gold sequence is being detected. Accordingly one may expand the width of memory 2902 to a number or word representing any of the set of Gold sequences.

The memory line enabled by 2905 then shows [2 1 0 2 1 2 2 1] being the 7 most significant digits of the memory address of the next word and the ‘correctness indicator” symbol 1 for a specific Gold sequence. The enabled memory line may be temporarily stored in a clock controlled buffer 2925 to prevent race conditions as disclosed earlier as an aspect of the present invention. One should take care in the correct programming of the memory lines by closely following the consecutive words in the appropriate sequence, thereby realizing that the digits in the sequence are shown in the order of appearance. For capturing the most significant digits one should ‘read’ the digits in a word in reverse order from their appearance in the sequence. The enabled memory element in column 2902 will provide for instance a 1 when the enabled memory line is at an address that represents a word in sequence to be detected. If an address does not represent a valid Gold word, as shown in the next line, the column 2902 at this address will comprise for instance a 0.

The following will happen starting at address line [2 1 0 2 1 2 2 1] with current sequence symbol being a 0:
1. The line 2905 in FIG. 29 is enabled, so outputs 2910 to 2917, possibly through buffer 2925, and will provide the content of the memory line [2 1 0 2 1 2 2 1] being the last 7 digits of the new address. Assume the first digit of the new address 0 is provided by a next symbol of the incoming sequence on 2909.
2. The content of 2902 at the enabled memory line at 2905 will be provided on 2920. The input 2920 provides its signal to a circuit 2921. Circuit 2291 may be an adder plus a decision circuit. For instance the decision circuit may be reset to 0 after a certain sum is reached by the adder and detection of a sequence was achieved. The decision circuit may also make decisions on resetting the adder to 0. The decision circuit is controlled by a clock signal 2922 which is synchronized with clock signal 2918.
3. On a clock-pulse provided by 2918 the new address will be enabled. And the total process will repeat itself from step 1.

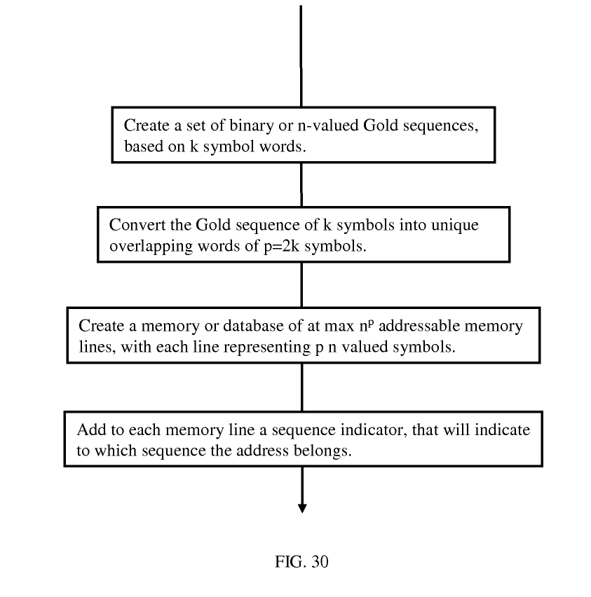

A process of creating an addressable memory to detect a Gold sequence of n-valued symbols is shown in diagram in FIG. 30. One can make arrangements in the address decoder to limit the number of memory lines by using translation tables, which may include Content Addressable Memories, thereby providing a limited number of addresses (and memory line) to undesirable words.

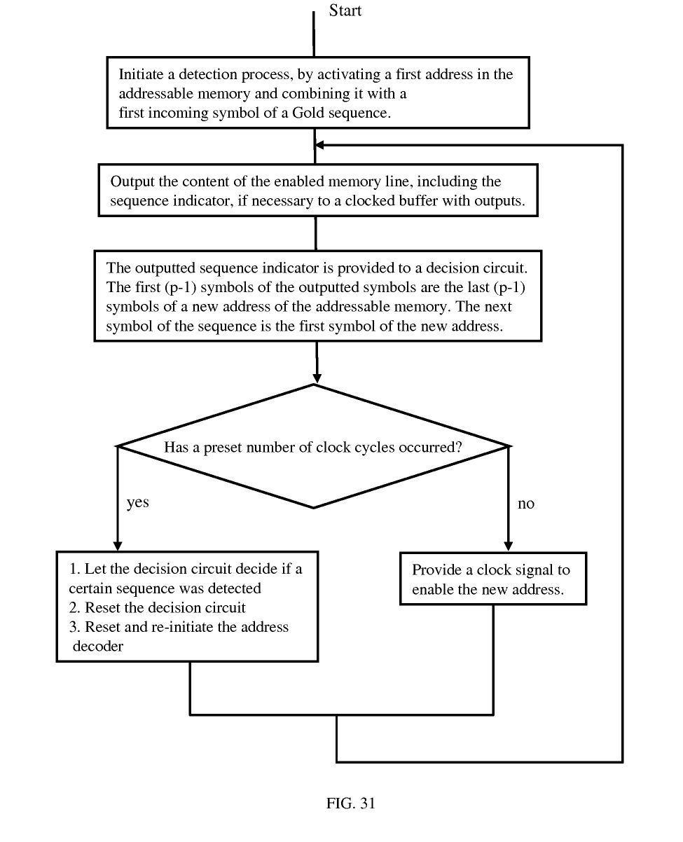

The process of detection is shown in the flow diagram of FIG. 31.

When a low Symbol Error Ratio is expected the detection process being an aspect of the present invention is self synchronizing. The method may initially lose track during the first 8 symbols of a next sequence if an error occurs. However the next and assumed to be correct symbols will shift into the memory and at the 9^{th} symbol the method will be back on track. One can modify the detection circuit 2921 in such a way that it will accept a certain number of symbols not being 1 (for instance 8 0s) when 1s are expected. Especially when the counter has a sum well above 0, it is almost certain that a symbol error has occurred. One can create and implement different detection rules into detector 2921. Another situation arises when the incoming sequence is not the one to be detected. In that case no word will be detected and circuit 2921 will for instance only receive 0s or other symbols not being 1. One may limit the number of address lines by using a content addressable translation table that translates for expected words and provides a 0 for all not expected words or addresses.

One can assign several different sequences to the detector of FIG. 29. This may be implemented by setting (for this ternary 8 symbol word example) for example the detection level at 65, assuming 73 words and 8 steps to flush the address line. Every time a level 65 is reached (if no errors occur) a sequence is detected and a sequence detect’ signal is provided on 2923 and the detector is reset to 0. It should be clear to those skilled in the art that other detection schemes can be implemented. For instance one may assign a 1 when a word that is part of one sequence is detected, a 2 when that word is part of another sequences or even more symbols when the word is part of yet another sequence. The level reached by the detector after a certain number of clock-pulses (73 for this ternary case) will indicate which sequence was detected. Other detection schemes are also possible. For example because words only occur in one sequence one may take into account the possibility of errors in the sequence and accept a count of for instance 50% of the maximum.

The method previously described to detect binary or n-valued Gold sequences is self-synchronizing. An address will be completely flushed after a number of symbols. Because of its fundamental approach of self-synchronization by memory elements all addresses have to occur if one does not apply some translation table based on for instance content addressable memories.

One can limit the use of memory by limiting the requirement of all addresses to have a memory line attached. One way to do that is by synchronizing the detector to a certain starting moment. Another way is to keep at least a full address in a writable memory like a RAM and use the content of the memory to find a value in a Look-up Table type of circuit like a Content Addressable Memory.

It is another aspect of the present invention to detect a sequence like a binary or an n-valued Gold sequence by means of applying a deserializer with memory capabilities to be used as an address for a look-up table or addressable secondary memory to find a specific value that will contribute to detection.

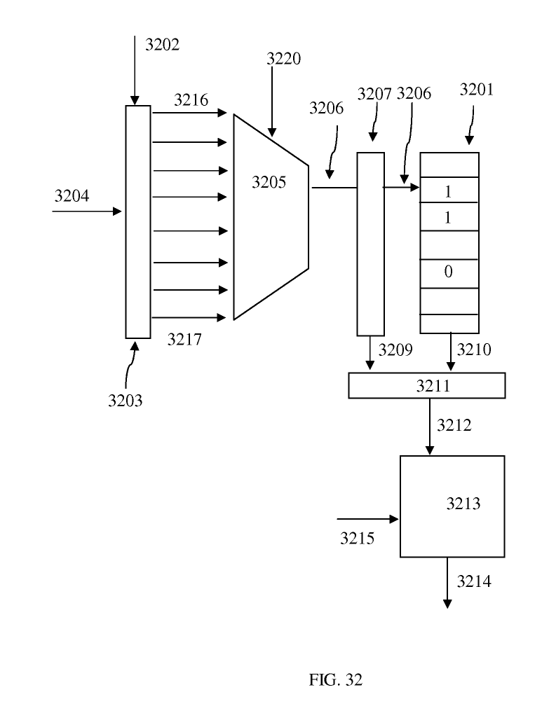

As an illustrative example the detection of the ternary 80 symbol Gold sequence with 73 overlapping 8 symbol words is used. This is shown in the diagram of FIG. 32. A sequence is provided on input 3202 on deserializer 3203. The deserializer is controlled by a clock signal provided on 3204. The deserialized signal of 8 symbols is made available at 8 individual parallel outputs from 3203 of which the top output is shown as 3216 and the eighths output is the bottom output and is shown as 3217. One may decide if these outputs are enabled at every new symbol or for instance as consecutive (instead of overlapping) words. This may be determined by additional circuitry controlled by the clock signal on 3204. It is assumed that the sequence is not synchronized in the sense that it is not known where the word is located compared to the beginning of the sequence. The 8 outputs are provided to an address decoder 3204 which will enable an input 3206 to a memory line in memory 3206. The address decoder may be controlled by a clock signal 3220. The enabling input is also provided to a circuit 3207 that will provide a signal on an output 3209 indicating that a memory line is enabled. Assume that the deserialized word is part of a valid Gold sequence, accordingly it will enable a memory line that corresponds with a confirming value 1 in memory 3201. If the word was not part of a valid Gold sequence, the value at that address would have a different value than 1. For instance it could then be 0 or 2. The content of the memory address that was enabled is provided on output 2410. One can of course also an indicator using more than 1 symbol. A compare circuit 3211 tests if 3209 is enabled and if 3210 provides a 1, and if so provides a signal (for instance 1) on an output 3212. Circuit 3213 adds a 1 to a sum when 3210 provides a 1. When the sum reaches a preset number it may be decided that a sequence was detected and a “sequence detected” signal is provided on 3214. The circuit 3213 is controlled by a control signal on input 3215. This input provides a reset signal that resets the sum to 0 and thus restarts a detection cycle.

This method may be adapted to allow for smaller memories and for lower clock rates as the deserializer may just sample the received sequence. For instance some form of start of sequence, perhaps in the form of a separate pilot signal may be applied. In that case one may just sample the received sequence. Confidence in the quality of the received sequence in Symbol Error Ratio will determine the sample rate and detection rules. This method can be used to detect many different sequences from the set of Gold sequences. If enough memory is available, one may implement a detector that detects all sequences and program the detector on which sequence a ‘sequence detect’ signal should be generated on 3214 and how a detected sequence should be represented. One way may be to have different ‘sequence detect’ outputs instead of one, wherein a specific detected sequence will enable a specific output. Theoretically a detector for a Gold sequence provided by one aspect of the current invention only requires the error free detection of one word.

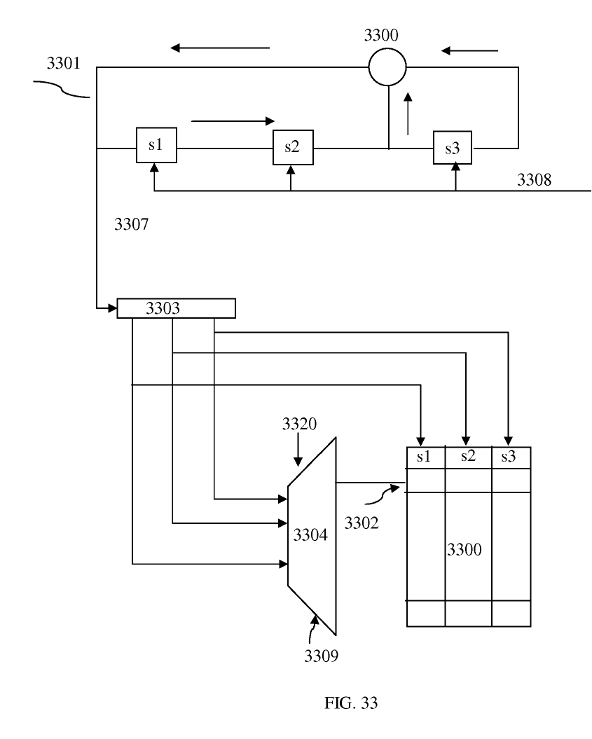

One aspect of the present invention is to provide a method to use volatile memory to use the create memory solutions. It is not required to pre-fill a memory with the data representing states of an LFSR or composite LFSRs for Gold sequences. FIG. 33 shows how a memory 3300 can be initialized and be filled with appropriate data by running an LFSR 3301. The LFSR is initiated and the generated sequence is inputted to a deserializer 3303. The deserializer outputs the deserialized symbols as an address as well as the to be stored content of memory 3300. One may add to each line a required indicator symbol or symbols. An additional advantage is that at initiation of the memory one can run the LFSR at a low clock rate and just once. After initializing the memory the LFSR is no longer required and can be disabled.

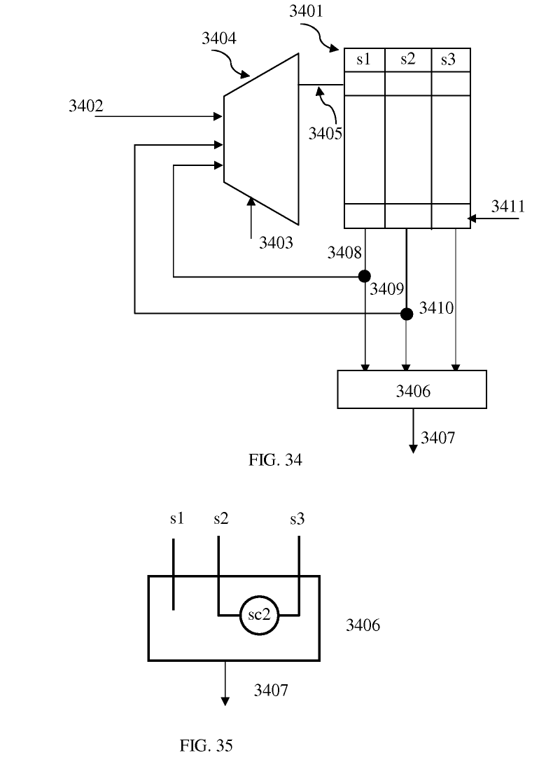

In summary, one aspect of the present invention is the realization of an n-valued LFSR by way of an addressable memory. An illustrative diagram is shown in FIG. 34. It shows a diagram of a 3-element n-valued LFSR realization by a clock controlled addressable memory. The three elements are for illustrative purposes and it should be clear that the approach is applicable to an LFSR of any size. The realization of the illustrative example uses an addressable memory 3401. The memory has n³ memory lines (as k=3 in the example). Each memory line can hold a word of 3 n-valued symbols. A memory line is enabled by an output of an address decoder. An output (one of n³ in this example) of the address decoder is enabled when an address is inputted on the address decoder 3404 and a clock signal is provided on 3403. An enabled memory line provides its individual symbols on outputs, in this case on the outputs 3408, 3409 and 3410. There are different ways to keep a memory line enabled after a clock signal is switched off. One way is to have the address decoder 3404 keep enabling an enabled output until a next clock pulse is provided. Another way may be to temporarily store the outputted symbols of a memory line in a clock controlled buffer 3411. Both approaches will prevent race conditions. In an LFSR the state of a shift register is used for feedback through taps from the elements of the shift register into reversible n-valued functions resulting in a single output, such as output 102 as shown in FIG. 1. The functions and tap configuration can be selected and configured in different ways. However the result is schematically that outputs from shift register elements are inputted to a processing unit executing n-valued logic functions and providing a single n-valued symbol on an output. This is shown in FIG. 34 wherein the outputs 3408, 3409, 3410 of a memory line (representing a state of the shift register) 3405, are provided to a LFSR logic unit 3406 and outputting a result on 3407.

FIG. 35 shows in greater detail how an LFSR logic unit can be visualized. Assume that the unit 3406 has to implement the feedback or LFSR logic of the circuit of FIG. 25. In fact one has an n-valued logic circuit just using 1 logic function 2502. The inputs to such a logic circuit are of course the outputs of the shift register elements connected to the taps. It is easy to see that the feedback or LFSR logic can be represented as shown in FIG. 35. There is only the function sc2 to take into account in this case. The output of the first element is not used in determining the output signal. Though the signal s1 is provided it is not used and could be omitted in this case. One can thus replace the LFSR logic circuitry by a logic unit 3407 with as input the output of an enabled memory line, though not all outputs have to be used. The logic unit has a single output 3407.

Accordingly 3407 in FIG. 34 corresponds with output 102 in FIG. 1 or FIG. 2. Further more the first (k−1) symbols of a current state of an LFSR form the last (k−1) symbols of a new state of the LFSR. Accordingly the first two symbols of the enabled memory line are the last two symbols of the next states. The address decoder has k=3 inputs. The symbols on the two last inputs are provided by the first two outputs of the enabled memory line. A first input 3402 to the address decoder is also provided. This input corresponds with input 101 of the LFSR of FIG. 1 and FIG. 2. Accordingly 3402 may be considered the input of the LFSR. In case of the LFSR based circuit being a sequence generator input 3402 may be connected to output 3407. In case of the circuit being a scrambler an additional reversible n-valued logic function is used with its output connected to input 3402, one input connected to output 3407 and an n-valued sequence provided on its other input. The output of the function is also the output of the scrambler. In case of a descrambler the LFSR also has an additional reversible n-valued logic function with one input connected to output 3407. An n-valued sequence is provided to the second input of the function. The same n-valued sequence in case of the descrambler is provided to the input 3402. The output of the function in that case is the output of the descrambler.

The content of the memory reflects all possible states of the LFSR. In case one uses the LFSR in a sequence generator circuit one may omit the forbidden state.

It should be clear that the n-valued circuits in the block diagrams of the different aspects of the present invention may be arranged in different ways and apply different components. One may use binary logic circuits, wherein a non-binary symbol is represented by a plurality of bits. One may apply A/D and D/A converters to process and create n-valued signals. One may use programmable processors such as microprocessors or signal processors. One may also use Look-up Tables or other logic circuits, including n-valued switching circuits as disclosed in U.S. Pat. No. 6,133,754, by Edgar Danny Olson entitled: Multiple-valued logic circuit architecture; supplementary symmetrical logic circuit structure (SUS-LOC). One may apply different functional blocks or omit usage of some the applied blocks as shown in the drawings of the present invention. It should also be clear that such changes will not materially change the underlying methods of the present invention. It should also be clear that the methods can be applied to sequences and symbols in different n-valued logics or representations.

The LFSRs used in different aspects of the present invention are not using multipliers or n-valued reversible inverters. As shown in cited U.S. patent application Ser. No. 10/935,960 one can replace an n-valued reversible logic function with two inputs and an output, with reversible n-valued inverters at one or at both inputs by a single n-valued reversible logic function. Accordingly the different aspects of the present invention also apply to LFSRs that use n-valued reversible inverters.

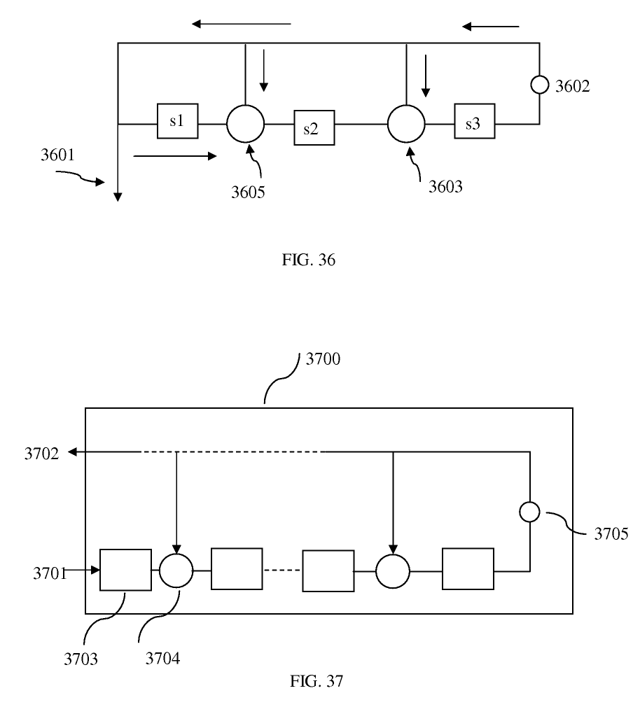

The present invention deals in many aspects with LFSRs in Fibonacci configuration. Application of the different aspects of the present invention to LFSRs in Galois configuration is fully contemplated and includes: sequence generators, scramblers, descramblers and coders such as Reed Solomon coders. In order to illustrate the use of LFSRs in Galois configuration with addressable memories the diagram of FIG. 36 is provided. FIG. 36 shows an LFSR based sequence generator in Galois configuration and includes in the illustration an n-valued shift register with elements s1, s2 and s3; reversible n-valued logic functions 3603 and 3605; a reversible n-valued inverter 3602 and an output 3601. The LFSR is controlled by a clock signal which is not shown but assumed to be present.

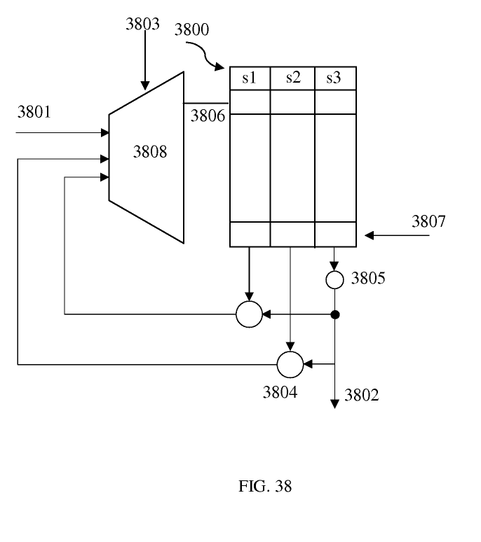

The generator of FIG. 36 uses an LFSR in Galois configuration. FIG. 37 shows a diagram of a general LFSR in Galois configuration 3700. The Galois LFSR has an input 3701 and an output 3702. It also has a shift register of which the first element is identified as 3703 in FIG. 37 and one or more reversible n-valued logic functions of which a function is identified as 3704. The LFSR may have an n-valued reversible inverter 3705. The LFSR of FIG. 37 can be adapted to be a sequence generator, a scrambler or to have another function. This is identical to the approach in the Fibonacci LFSR. In U.S. Provisional patent application Ser. No. 60/789,613, filed Apr. 5, 2006 entitled: Sequence Scramblers, Descramblers, Generators and Detectors in Galois Configuration, which is incorporated herein by reference in its entirety, the inventor shows how one can create equivalent Galois solutions to Fibonacci based LFSRs. FIG. 38 shows an addressable memory implementation of a Galois based LFSR as a further aspect of the present invention.

The LFSR of FIG. 38 is comprised of an addressable memory 3800. All shift register outputs elements are represented in a memory line. A memory line (for example 3806) in an addressable memory can be enabled by an address decoder 3808, which may be controlled by a clock 3803. All symbols stored in an enabled memory line will be outputted and are available on a series of individual outputs 3807. The content of each memory line reflects the present state of the LFSR and thus is identical to the address. It should be clear that a new content of the shift register (due to the logic functions) is not necessarily a shifted version of the previous content. The individual outputted symbols are provided to n-valued functions according to the Galois LFSR, for instance to a reversible n-valued logic function 3804 and to an n-valued reversible inverter 3805. In the configuration as shown in FIG. 37 (but other configurations are fully contemplated as is shown in the earlier cited Provisional Patent Application No. 60/789,613) the output of the inverter is also the output 3802 of the LFSR. The symbols outputted on the n-valued reversible logic functions and on the shift register elements not connecting to a function will determine the next state of the LFSR.

A special case is the last element outputted on the inverter. The output of the inverter is the output of the LFSR in the present illustration. The LFSR also has an input, which is the input to the first element of the LFSR or in FIG. 38 an unconnected input to the address decoder 3808. By connecting 3801 and 3802 the circuit is made into a sequence generator. One may also insert a reversible n-valued logic function with a first input and a second input and an output. The first input may be connected to output 3802, an n-valued sequence is provided on the second input and a second sequence is provided on the output of the inserted function. By connecting the output of the device to output 3801 one has created a Galois LFSR based scrambler. One may create a Galois descrambler or a Galois detector also by inserting functions into the LFSR.

N-valued LFSR based scramblers and corresponding descramblers have identical LFSRs as defined in this specification. They differ in how signals are routed through a reversible n-valued logic function and connected to an LFSR. As shown extensively in U.S. Non-Provisional patent application Ser. No. 10/935,960 which is incorporated herein by reference in its entirety, the connecting n-valued logic function of the descrambler is the reverse of the connecting n-valued logic function of a scrambler. A function being “the reverse” of another function is the same as stating that one function reverses the other function. In formula: assume n-valued logic functions ‘sc1’ and ‘scr’. Each function has two inputs and one output. For the function ‘sc1’ with inputs ‘a’ and ‘b’ and output ‘c’ one can state: a sc1 b=c. If for the function ‘scr’ the following statement is valid: c scr b=a, then function ‘scr’ is a reverse of function ‘sc1’ or also function: ‘scr’ reverses the function ‘sc1’.

While there have been shown, described and pointed out fundamental novel features of the invention as applied to preferred embodiments thereof, it will be understood that various omissions and substitutions and changes in the form and details of the device illustrated and in its operation may be made by those skilled in the art without departing from the spirit of the invention. It is the intention, therefore, to be limited only as indicated by the scope of the claims appended hereto.

The following patent applications, including the specifications, claims and drawings, are hereby incorporated by reference herein, as if they were fully set forth herein: (1) U.S. Non-Provisional patent application Ser. No. 10/935,960, filed on Sep. 8, 2004, entitled TERNARY AND MULTI-VALUE DIGITAL SCRAMBLERS, DESCRAMBLERS AND SEQUENCE GENERATORS; (2) U.S. Non-Provisional patent application Ser. No. 10/936,181, filed Sep. 8, 2004, entitled TERNARY AND HIGHER MULTI-VALUE SCRAMBLERS/DESCRAMBLERS; (3) U.S. Non-Provisional patent application Ser. No. 10/912,954, filed Aug. 6, 2004, entitled TERNARY AND HIGHER MULTI-VALUE SCRAMBLERS/DESCRAMBLERS; (4) U.S. Non-Provisional patent application Ser. No. 11/042,645 , filed Jan. 25, 2005, entitled MULTI-VALUED SCRAMBLING AND DESCRAMBLING OF DIGITAL DATA ON OPTICAL DISKS AND OTHER STORAGE MEDIA; (5) U.S. Non-Provisional patent application Ser. No. 11/000,218, filed Nov. 30, 2004, entitled SINGLE AND COMPOSITE BINARY AND MULTI-VALUED LOGIC FUNCTIONS FROM GATES AND INVERTERS; (6) U.S. Non-Provisional patent application Ser. No. 11/065,836 filed Feb. 25, 2005, entitled GENERATION AND DETECTION OF NON-BINARY DIGITAL SEQUENCES; (7) U.S. Non-Provisional patent application Ser. No. 11/139,835 filed May 27, 2005, entitled MULTI-VALUED DIGITAL INFORMATION RETAINING ELEMENTS AND MEMORY DEVICES; (8) U.S. Provisional Patent Application No. 60/695,317 filed on Jun. 30, 2005 entitled CREATION AND DETECTION OF BINARY AND NON_BINARY PSEUDO-NOISE SEQUENCES NOT USING LFSR CIRCUITS; (9) U.S. Provisional Patent Application Ser. No. 60/789,613, filed Apr. 5, 2006 entitled: SEQUENCE SCRAMBLERS, DESCRAMBLERS, GENERATORS AND DETECTORS IN GALOIS CONFIGURATION.

What is claimed:

1. An apparatus for implementing an n-valued LFSR with n≧2 of k elements with k≧2 comprising:
an addressable memory with n^{k} memory lines, wherein:
each memory line has an address;
each memory line can be individually enabled;
each memory line is able to store k symbols; and
each memory line when enabled outputs k symbols on k individual memory line outputs;
an address decoder with k inputs;
d devices, each implementing a reversible n-valued logic function, connected to (d+1) memory line outputs with d+1≦k and connected to realize an n-valued LFSR logic unit with an output adapted to be an apparatus output;
(k−1) of the k memory line outputs being connected to (k−1) inputs of the address decoder; and
a k^{th} input of the address decoder not being connected to a memory line output and being an apparatus input.

2. The apparatus as claimed in claim 1, further comprising a connection between the apparatus output and the apparatus input and wherein the output of the apparatus is adapted for outputting a sequence of n-valued symbols.

3. The apparatus as claimed in claim 2, wherein the memory line representing a forbidden word is omitted.

4. The apparatus as claimed in claim 1, for scrambling a first sequence of n-valued symbols into a second sequence of n-valued symbols, further comprising:
a device with a first and a second input and an output implementing a first reversible n-valued logic function wherein:
the first input of the device is connected to the apparatus output;
the second input receives the first sequence of n-valued symbols; and
the output of the device outputs the second sequence of n-valued symbols; and
a connection between the output of the device and the apparatus input.

5. The apparatus as claimed in claim 1, for descrambling a first sequence of n-valued symbols into a second sequence of n-valued symbols, further comprising:
a device with a first and a second input and an output implementing a first reversible n-valued logic function wherein:
the first input of the device is connected to the apparatus output;
the second input of the device receives a first sequence of n-valued symbols;
the output of the device provides the second sequence of n-valued symbols; and
a connection between the second input of the device and the apparatus input to provide the first sequence on the apparatus input.

6. The apparatus as claimed in claim 5, wherein the first sequence is created by a scrambler having a device implementing a second reversible n-valued logic function and the first reversible n-valued logic function reverses the second reversible n-valued logic function.

7. An apparatus for self synchronized detection of a Gold sequence formed by two different n-valued LFSRs of k elements, comprising:
an addressable memory with a plurality of memory lines that can be individually enabled and that each can store (2k−1+q) n-valued symbols and having (2k−1+q) individual memory outputs for an enabled memory line, wherein:
(2k−1) of the (2k−1+q) symbols are part of a unique word of 2k n-valued symbols that occurs in one of a set of Gold sequences;
q symbols of the (2k−1+q) symbols are an indicator of the specific Gold sequence that a word corresponding to an address belongs to;
an address decoder with 2k individual inputs;
(2k−1) individual memory outputs being connected to (2k−1) individual inputs of the address decoder; and
one first individual input of the address decoder not being connected to one of 2k−1 individual memory outputs being adapted to accept a sequence of n-valued symbols.

8. The apparatus as claimed in claim 7, further comprising a module for processing the q indicator symbols.

9. A method for implementing an n-valued LFSR of k elements comprising:
applying an addressable memory with n^{k} memory lines wherein each memory line can store k symbols and each of the n^{k} memory lines can be individually enabled;
outputting the k symbols of an enabled memory line on k individual memory outputs;
inputting (k−1) of k individual memory outputs to (k−1) individual inputs of an address decoder of the addressable memory having k individual inputs;
processing the symbols provided on the k individual memory outputs according to an n-valued LFSR logic unit and providing the result on a first output; and
adapting a k^{th} input of k individual inputs of the address decoder as a first input to receive an n-valued symbol.

10. The method as claimed in claim 9, for generating a sequence of n-valued symbols further comprising:
a) initiating a first address on the address decoder;
b) providing an n-valued symbol available on the first output to the first input;
c) outputting the symbol available on the first output on a system output;
d) initiating a next address; and
e) repeating steps b) to d) until all n-valued symbols of the sequence have been generated.

11. The method as claimed in claim 10, wherein the addressable memory has no memory line representing a forbidden state for generating a sequence.

12. The method as claimed in claim 9, for scrambling a first sequence of n-valued symbols into a second sequence of n-valued symbols, further comprising:
a) initiating a first address on the address decoder;
b) providing an n-valued symbol available on the first output to a first input of a reversible n-valued logic function with a first and second input and an output;
c) providing an n-valued symbol of the first sequence of n-valued symbols on the second input of the reversible n-valued logic function;
d) generating an n-valued symbol of the second sequence of n-valued symbols on the output of the reversible n-valued logic function resulting from the symbols on the first and second input of the reversible n-valued logic function;
e) providing the n-valued symbol of the second sequence available on the output of the reversible n-valued logic function to the first input and to a system output;
f) initiating a next address; and
g) repeating steps b) to f) until all symbols of the first sequence have been scrambled.

13. The method as claimed in claim 9, for descrambling a first sequence of n-valued symbols into a second sequence of n-valued symbols, further comprising:
a) initiating a first address on the address decoder;
b) providing a symbol available on the first output to a first input of a first reversible n-valued logic function with a first and second input and an output;
c) providing an n-valued symbol of the first sequence of n-valued symbols on the second input of the first reversible n-valued logic function and on the first input;
d) generating an n-valued symbol of the second sequence on the output of the first reversible n-valued logic function resulting from the symbols on the first and second input of the first reversible n-valued logic function;
e) providing the n-valued symbol of the second sequence on the output of the first reversible n-valued logic function to a system output;
f) initiating a next address; and
g) repeating steps b) to f) until all n-valued symbols of the first sequence have been descrambled.

14. The method as claimed in claim 13, wherein the first sequence is created by a scrambling method applying a second reversible n-valued logic function and the first reversible n-valued logic function reverses the second reversible n-valued logic function.

15. The method as claimed in claim 13, wherein the first sequence is created by a scrambling method applying an addressable memory that is initiated on a second address and the first address is identical to the second address.

16. A method for self synchronized detection of a Gold sequence formed by two n-valued LFSRs of k elements from a first sequence of n-valued symbols, comprising:
a) initializing an addressable memory with at plurality of memory lines which can be individually addressed by an address decoder with 2k individual inputs wherein:
each memory line can store (2k−1+q) n-valued symbols;
an enabled memory line has (2k−1+q) individual memory outputs;
(2k−1) of the (2k−1+q) symbols stored in each memory line are part of a unique word of 2k n-valued symbols that occurs in one of a set of Gold sequence; and
q symbols of the (2k−1+q) symbols are an indicator of a Gold sequence that a word corresponding to an address belongs to;
(2k−1) individual memory outputs being connected to (2k−1) individual inputs of the address decoder;
b) initiating a first address of the addressable memory;
c) providing an n-valued symbol of the first sequence on a first individual input of the address decoder not being connected to one of 2k−1 individual memory outputs;
d) outputting the q symbols of the enabled memory line representing the indicator to a processing module with an output;
e) initiating a next address; and
f) repeating steps c) to e) a pre-determined number of times.

17. The method as claimed in claim 16, wherein the output of the processing module provides a confirmation signal when a predefined criterion of indicators has been met.

18. A method for detection of a Gold sequence formed by n-valued LFSRs of k elements from a first sequence of n-valued symbols comprising:
a) initializing an addressable memory with at plurality of memory lines which can be individually addressed by an address decoder with 2k individual inputs wherein:
each memory line stores q indicator symbols which are an indicator of a specific Gold sequence;
b) deserializing 2k symbols of the first sequence as an address for the address coder;
c) enabling a memory line corresponding with the address formed by the deserialized 2k symbols;
d) outputting q indicator symbols to a processing module with an output; and
e) repeating steps b) to d) a predefined number of times.

19. The method as claimed in claim 18, wherein the output of the processing module provides a confirmation signal when a predefined criterion of indicators has been met.
